(19) United States
(12) Patent Application Publication
(10) Pub. No.: US 2025/0081442 A1
(43) Pub. Date: Mar. 6, 2025

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Kang Sik CHOI, Gyeonggi-do (KR)

(21) Appl. No.: 18/429,438

(22) Filed: Feb. 1, 2024

(30) Foreign Application Priority Data
Aug. 31, 2023 (KR) 10-2023-0115452

(51) Int. Cl. H10B 12/00

(52) U.S. Cl. CPC H10B 12/482

(57) ABSTRACT

A semiconductor device includes a common conductive line extending in a first direction; a memory cell array including a plurality of horizontal layers stacked in the first direction while sharing the common conductive line; and a selector structure operatively coupled to the common conductive line, wherein the selector structure includes, a plurality of select transistors stacked in the first direction; and a selector commonly coupled to the select transistors.

### CROSS-REFERENCE TO RELATED APPLICATIONS

The present application claims priority under 35 U.S.C 119(a) to Korean Patent Application No. 10-2023-0115452, filed on Aug. 31, 2023, which is incorporated herein by reference in its entirety.

### BACKGROUND

### 1. Field

Various embodiments of the present invention relate to a semiconductor device, and more particularly, to a semiconductor device including three-dimensional memory cells, and a method for fabricating the semiconductor device.

### 2. Description of the Related Art

In order to cope with the demands for large capacity and miniaturization of memory devices, a technology for providing a three-dimensional (3D) memory device in which a plurality of memory cells are stacked has been proposed.

### SUMMARY

Various embodiments of the present invention are directed to a semiconductor device including highly integrated memory cells, and to a method for fabricating the semiconductor device.

In accordance with an embodiment of the present invention, a semiconductor device includes a common conductive line extending in a first direction; a memory cell array including a plurality of horizontal layers stacked in the first direction while sharing the common conductive line; and a selector structure operatively coupled to the common conductive line, wherein the selector structure includes, a plurality of select transistors stacked in the first direction; and a selector commonly coupled to the select transistors.

In accordance with another embodiment of the present invention, a method for fabricating a semiconductor device includes forming a stack body by sequentially forming a lower-level stack body and an upper-level stack body; forming a conductive line that passes through the lower-level stack body and the upper-level stack body; forming a memory cell array that includes a plurality of horizontal layers commonly coupled to the conductive line in the lower-level stack body; forming a plurality of select transistors that include selector-level horizontal layers commonly coupled to the conductive line in the upper-level stack body; and forming a selector that commonly passes through the selector-level horizontal layers. Forming the selector includes forming a selector level contact hole by etching the selector-level horizontal layers; and forming the selector in the selector level contact hole. The selector-level horizontal layers are stacked in a direction that the conductive line extends. The selector includes a semiconductor material, a metal, a metal silicide, a metal nitride, or a combination thereof. Forming the select transistors includes forming the selector-level horizontal layers; forming selector-level inter-level dielectric layers over the selector-level horizontal layers; and forming a plurality of selector-level horizontal conductive lines that extend in a direction that intersects with the selector-level horizontal layers, respectively. A horizontal length of the selector-level horizontal layers is greater than a horizontal length of the horizontal layers. The selector-level horizontal layers and the horizontal layers include monocrystalline silicon, polysilicon, or an oxide semiconductor material. Forming the memory cell array includes forming horizontal conductive lines extending in a direction that intersects with the horizontal layers, respectively; and forming data storage elements that are coupled to the horizontal layers, respectively. Each of the lower-level stack body and the upper-level stack body includes a stack of silicon germanium layers and monocrystalline silicon layers.

In accordance with an embodiment of the present invention, a semiconductor device includes a common conductive line extending vertically in a first direction; a memory cell array including a plurality of horizontal layers that are vertically stacked in the first direction while sharing the common conductive line; and a selector structure operatively coupled to the common conductive line, wherein the selector structure includes a plurality of select transistors that are stacked vertically in the first direction; and a selector commonly coupled to the select transistors.

These and other features and advantages of the present invention will become better understood by the skilled persons in this art from the following drawings and the detailed description of example embodiments of the present invention.

### BRIEF DESCRIPTION OF THE DRAWINGS

FIG. 1A is a perspective view schematic illustrating a semiconductor device in accordance with an embodiment of the present invention.

FIG. 1B is a cross-sectional view schematic illustrating a semiconductor device in accordance with an embodiment of the present invention.

FIG. 2 is a cross-sectional view schematic taken along a line A1-A1′ shown in FIG. 1B.

FIG. 3 is a cross-sectional view schematic taken along a line A2-A2′ shown in FIG. 1B.

FIGS. 4 to 29 are plan view schematics illustrating a method for fabricating the semiconductor devices in accordance with embodiments of the present invention.

FIGS. 30A to 30C are cross-sectional view schematics illustrating a method for fabricating a semiconductor device in accordance with another embodiment of the present invention.

FIGS. 31 to 33 are perspective view schematics illustrating semiconductor devices in accordance with other embodiments of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

According to an embodiment of the present invention described below, memory cells may be vertically stacked to increase the memory cell density and reduce parasitic capacitance.

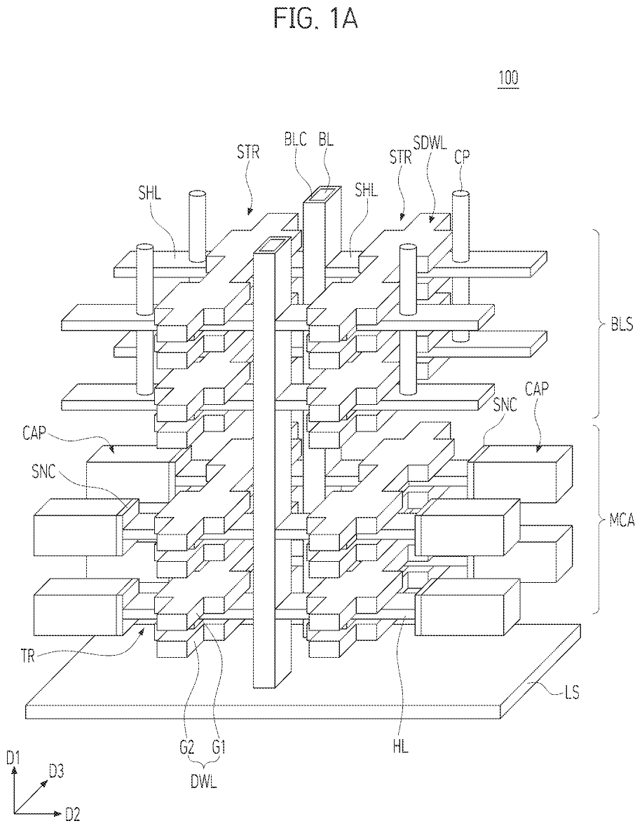

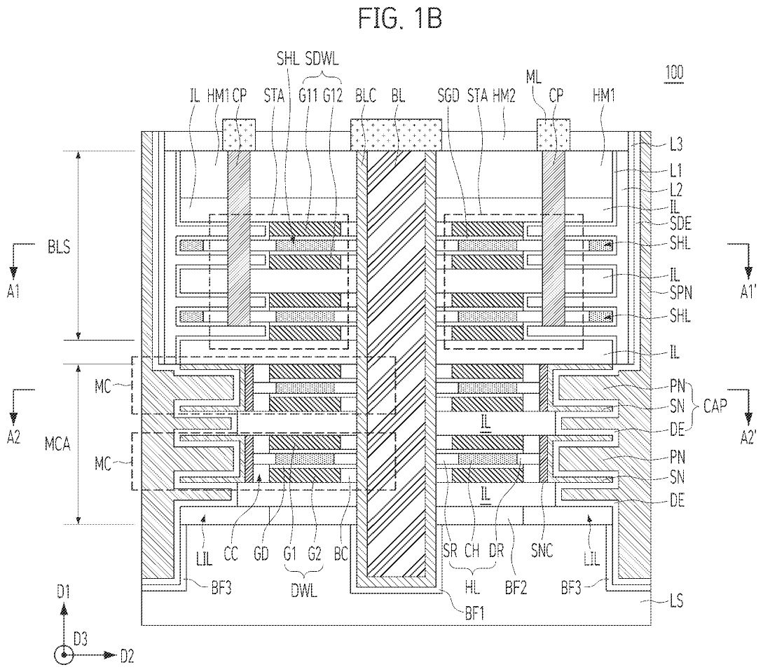

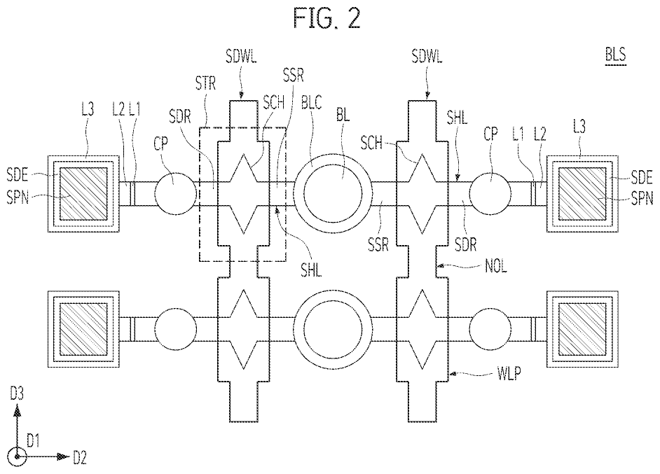

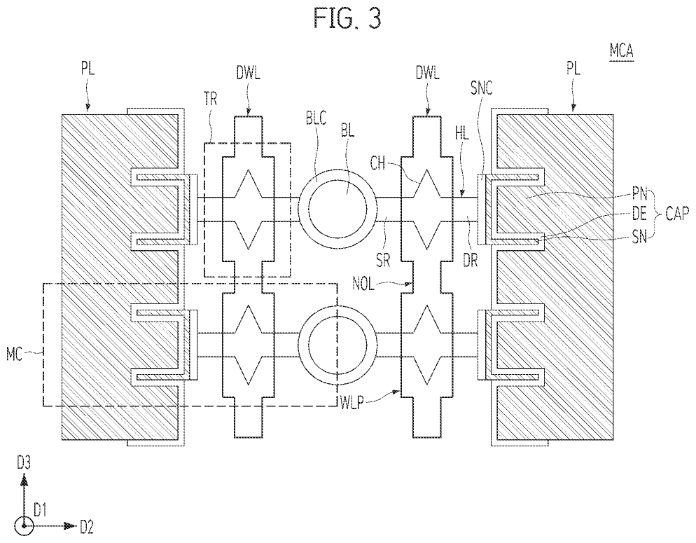

FIG. 1A is a perspective view schematic illustrating a semiconductor device in accordance with an embodiment of the present invention. FIG. 1B is a cross-sectional view schematic illustrating a semiconductor device in accordance with an embodiment of the present invention. FIG. 2 is a cross-sectional view schematic taken along a line A1-A1′ shown in FIG. 1B. FIG. 3 is a cross-sectional view schematic taken along a line A2-A2′ shown in FIG. 1B.

Referring to FIGS. 1A to 3, the semiconductor device 100 may include a memory cell array MCA and a selector structure BLS. The memory cell array MCA may include a plurality of memory cells MC. The memory cell array MCA may include a three-dimensional array of memory cells MC. The three-dimensional array of memory cells MC may include a column array of memory cells MC and a row array of memory cells MC. The column array of memory cells MC may include a plurality of memory cells MC that are stacked in a first direction D1. The row array of memory cells MC may include a plurality of memory cells MC that are horizontally arranged in a second direction D2 and a third direction D3.

Each memory cell MC may include a first conductive line BL, a switching element TR, and a data storage element CAP.

The memory cell array MCA may include sub-memory cell arrays that are adjacent to each other in the second direction D2. The sub-memory cell array may have a mirror-type structure in which two memory cells MC share the first conductive line BL. According to another embodiment of the present invention, the semiconductor device 100 may further include sub-memory cell arrays having a mirror-type structure in which two memory cells MC share the second electrode PN of the data storage element CAP. The memory cell array MCA may include a plurality of sub-memory cell arrays in which memory cells MC are vertically stacked in the first direction D1. The memory cell array MCA may include a plurality of sub-memory cell arrays that are arranged horizontally in the third direction D3. According to another embodiment of the present invention, the memory cell array MCA may include a plurality of sub-memory cell arrays that are arranged in the second direction D2. For example, in the second direction D2, the data storage element CAP, the switching element TR, the first conductive line BL, and the switching element TR may be alternately arranged in the mentioned order.

Inter-cell dielectric layers IL may be disposed between the memory cells MC that are stacked in the first direction D1. The inter-cell dielectric layers IL may include silicon oxide. The inter-cell dielectric layers IL may also be referred to as ‘horizontal inter-cell dielectric layers.’ The first top dielectric layer HM1 may be disposed over the uppermost-level inter-cell dielectric layer IL.

The memory cell array MCA may include a plurality of second conductive lines DWL vertically stacked in the first direction D1. The memory cell array MCA may include a plurality of horizontal layers HL that are stacked vertically in the first direction D1. The memory cell array MCA may include a plurality of data storage elements CAP vertically stacked in the first direction D1. The memory cell array MCA may include a plurality of first conductive lines BL that are spaced apart from each other in the third direction D3. The first conductive lines BL may each extend in the first direction D1. The first conductive lines BL may each have a pillar shape, for example, with a rectangular shape cross-section.

The memory cell array MCA may be disposed over the lower structure LS. The selector structure BLS may be disposed over the memory cell array MCA. The selector structure BLS may be disposed to overlap with the memory cell array MCA.

The first conductive line BL may be vertically oriented in the first direction D1. The first conductive line BL may include a bit line. The first conductive line BL may also be referred to as a vertical conductive line, a vertically-oriented bit line, a vertically-extending bit line, or a pillar-shaped bit line. The first conductive line BL may include a conductive material. The first conductive line BL may include a silicon-based material, a metal-based material, or a combination thereof. The first conductive line BL may include polysilicon, a metal, a metal nitride, a metal silicide, or a combination thereof. The first conductive line BL may include polysilicon, titanium nitride, tungsten, or a combination thereof. For example, the first conductive line BL may include a stack (TiN/W) of titanium nitride and tungsten.

The switching element TR may have a function of controlling voltage (or current) supply to the data storage element CAP during a data write operation and a data read operation performed on the data storage element CAP. The switching element TR may include a horizontal layer HL, an inter-level dielectric layer GD, and a second conductive line DWL. The second conductive line DWL may include a horizontal conductive line or a horizontal word line, and the horizontal layer HL may include an active layer. The switching element TR may include a transistor, and in this case, the second conductive line DWL may function as a gate electrode. The second conductive line DWL may also be referred to as a ‘horizontal gate electrode or a horizontal word line.’ The switching element TR may function as a cell transistor. The switching element TR may also be referred to as an ‘access element or a selection element’.

The horizontal layer HL may extend in the second direction D2 that intersects with the first direction D1. The second conductive line DWL may extend in the third direction D3 that intersects with the first direction D1 and the second direction D2. The first direction D1 may be a vertical direction, and the second direction D2 may be a first horizontal direction, and the third direction D3 may be a second horizontal direction. The horizontal layer HL may extend in the first horizontal direction (i.e., the second direction D2), and the second conductive line DWL may extend in the second horizontal direction (i.e., the third direction D3).

The horizontal layer HL may be horizontally oriented in the second direction D2 from the first conductive line BL. The second conductive line DWL may have a double structure. For example, the second conductive line DWL may include an upper horizontal line G1 and a lower horizontal line G2 that are facing each other with the horizontal layer HL interposed between them. An inter-level dielectric layer GD may be formed on the upper and lower surfaces of the horizontal layer HL. The inter-level dielectric layer GD may be formed to be in direct contact with the upper and lower surfaces of the horizontal layer HL. The upper horizontal line G1 may be disposed over the horizontal layer HL, and the lower horizontal line G2 may be disposed over the horizontal layer HL. The second conductive line DWL may include a pair of the upper and lower horizontal lines G1 and G2. In the second conductive line DWL, the same driving voltage may be applied to the upper and lower horizontal lines G1 and G2. For example, the upper and lower horizontal lines G1 and G2 may form a pair and be coupled to one memory cell MC. According to another embodiment of the present invention, different driving voltages may be applied to the upper and lower horizontal lines G1 and G2. In this case, one horizontal line disposed between the upper and lower horizontal lines G1 and G2 may function as a back gate or a shield gate.

Each of the upper and lower horizontal lines G1 and G2 may have a width in the second direction D2, for example, the width of an overlapping portion that overlaps with the horizontal layer HL, which is greater than the width of a non-overlapping portion that does not overlap with the horizontal layer HL. The second conductive line DWL may include a channel overlapping portion WLP and a channel non-overlapping portion NOL. The channel overlapping portion WLP refers to a portion that overlaps with a channel CH of the horizontal layer HL. The channel non-overlapping portion NOL refers to a portion that does not overlap with the horizontal layer HL. The channel overlapping portion WLP may have a cross shape or a rhombus shape. The channel overlapping portion WLP may fully overlap the channel CH. The second conductive line DWL extending in the third direction D3 may include a plurality of channel overlapping portions WLP. As the channel overlapping portions WLP and the channel non-overlapping portions NOL are alternately repeated in the third direction D3, the second conductive line DWL may have a notched sidewall.

From the perspective of a top view, the horizontal layer HL may have a cross shape or a rhombus shape. According to another embodiment of the present invention, the side surfaces of the horizontal layer HL may have a bent shape or a round shape.

The horizontal layer HL may include a semiconductor material. For example, the horizontal layer HL may include polysilicon, monocrystalline silicon, germanium, or silicon-germanium. According to another embodiment of the present invention, the horizontal layer HL may include an oxide semiconductor material. For example, the oxide semiconductor material may include Indium Gallium Zinc Oxide (IGZO). According to another embodiment of the present invention, the horizontal layer HL may include a conductive metal oxide.

The upper and lower surfaces of the horizontal layer HL may have a flat surface. The upper and lower surfaces of the horizontal layer HL may be parallel to each other in the second direction D2.

The horizontal layer HL may include a channel CH, a first doped region SR disposed between the channel CH and the first conductive line BL, and a second doped region DR disposed between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as ‘an active layer or a thin-body’. The channel overlapping portion WLP of the channel CH and the second conductive line DWL may overlap with each other. The channel CH may have a cross shape or a rhombus shape. The size of the channel overlapping portion WLP of the second conductive line DWL may be greater than that of the channel CH. The channel overlapping portion WLP of the second conductive line DWL may fully overlap with the channel CH.

The first doped region SR and the second doped region DR may be doped with impurities of the same conductivity type. The first doped region SR and the second doped region DR may be doped with an N-type conductive impurity or a P-type conductive impurity. The first doped region SR and the second doped region DR may include at least one impurity selected from arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may also be referred to as ‘first and second source/drain regions.’

The inter-level dielectric layer GD may be disposed between the horizontal layer HL and the second conductive line DWL. The inter-level dielectric layer GD may also be referred to as a gate dielectric layer. The inter-level dielectric layer GD may also be referred to as a horizontal layer side dielectric layer. The inter-level dielectric layer GD may include silicon oxide, silicon nitride, a metal oxide, a metal oxynitride, a metal silicate, a high-k material, a ferroelectric material, an anti-ferroelectric material, or a combination thereof. The inter-level dielectric layer GD may include SiO₂, Si₃N₄, HfO₂, Al₂O₃, ZrO₂, AlON, HfON, HfSiO, HfSiON, HfZrO, or a combination thereof. The inter-level dielectric layer GD may be formed by a thermal oxidation process of a semiconductor material.

The second conductive line DWL may include a metal-based material, a semiconductor material, or a combination thereof. The second conductive line DWL may include titanium nitride, tungsten, polysilicon, or a combination thereof. For example, the second conductive line DWL may include a TiN/W stack in which titanium nitride and tungsten are sequentially stacked. The second conductive line DWL may include an N-type work function material or a P-type work function material. The N-type work function material may have a low work function of approximately 4.5 eV or less, and the P-type work function material may have a high work function of approximately 4.5 eV or more. The second conductive line DWL may include a stack of a low work function material and a high work function material.

The data storage element CAP may include a memory element, such as a capacitor. The data storage element CAP may be arranged horizontally in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE disposed between the first electrode SN and the second electrode PN. The first electrode SN, the dielectric layer DE, and the second electrode PN may be horizontally arranged in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1, and the horizontal outer surfaces of the first electrode SN may extend horizontally in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. A portion of the outer surfaces of the first electrode SN may be electrically connected to the second doped region DR of the horizontal layer HL. The second electrode PN of the data storage element CAP may be coupled to a common plate PL.

The data storage element CAP may be a three-dimensional structure. The first electrode SN may have a three-dimensional structure, and the first electrode SN of the three-dimensional structure may have a horizontal three-dimensional structure that is oriented in the second direction D2. For example, in the three-dimensional structure, the first electrode SN may have a cylindrical shape. The cylindrical shape of the first electrode SN may include cylindrical inner surfaces and a cylindrical outer surface. A portion of the cylindrical outer surfaces of the first electrode SN may be electrically connected to the second doped region DR of the horizontal layer HL. A dielectric layer DE and a second electrode PN may be disposed on the cylindrical inner surfaces of the first electrode SN.

According to another embodiment of the present invention, the first electrode SN may have a pillar shape or a pylinder shape. The pylinder shape refers to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may be a stack (TiN/SiGe/WN) of titanium nitride/silicon germanium/tungsten nitride. In the titanium nitride/silicon germanium/tungsten nitride (TiN/SiGe/WN) stack, silicon germanium may be a gap-fill material that fills the inside of the first electrode SN, and titanium nitride (TiN) may serve as the second electrode PN of the data storage element CAP, and tungsten nitride may be a low-resistance material.

The dielectric layer DE may also be referred to as a capacitor dielectric layer or a memory layer. The dielectric layer DE may include silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium-based oxide (Zr-based oxide). The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and ZAZ stack may also be referred to as a zirconium oxide-based layer (ZrO₂-based layer). According to another embodiment of the present invention, the dielectric layer DE may be formed of hafnium-based oxide (Hf-based oxide). The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and HAH stack may also be referred to as a hafnium oxide-based layer (HfO₂-based layer). In the ZA stack, ZAZ stack, HA stack, and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material that has a greater band gap energy than the high-k material. The dielectric layer DE may include silicon oxide (SiO₂) as a high band gap material other than aluminum oxide (Al₂O₃). Leakage current may be suppressed by containing a high band gap material in the dielectric layer DE. The high band gap material may be thinner than a high-k material. According to another embodiment of the present invention, the dielectric layer DE may include a stack structure in which a high-k material and a high bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stack structure, aluminum oxide (Al₂O₃) may be thinner than zirconium oxide (ZrO₂) and hafnium oxide (HfO₂).

According to another embodiment of the present invention, the dielectric layer DE may include a high-k material and a high band gap material, and the dielectric layer DE may have a laminated structure in which a plurality of high-k materials and a plurality of high band gap materials are stacked, or a mixed structure in which a high-k material and a high band gap material are intermixed.

According to another embodiment of the present invention, the dielectric layer DE may include a ferroelectric material, an anti-ferroelectric material, or a combination thereof. For example, the dielectric layer DE may include HfZrO.

According to another embodiment of the present invention, the dielectric layer DE may include a combination of a high-k material and a ferroelectric material, a combination of a high-k material and an anti-ferroelectric material, or a combination of a high-k material or a ferroelectric material and an anti-ferroelectric material.

According to another embodiment of the present invention, an interface control layer may be further formed between the first electrode SN and the dielectric layer DE to improve leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced by another data storage material. For example, the data storage material may be a thyristor, a phase-change material, a Magnetic Tunnel Junction (MTJ), or a variable resistance material.

For example, the memory cell MC may include a thyristor, and the first conductive line BL may be a cathode line, and the data storage element CAP may be replaced by an anode line. Accordingly, the horizontal layer HL may include four semiconductor layers that are stacked in the second direction D2. The thyristor may include a first diode and a second diode that are coupled serially. When a forward bias of the same voltage is applied to the thyristor, the thyristor may have a high conductance state in which a large amount of current flows, or a low conductance state in which a small amount of current flows or no current flows. The memory cell MC according to this embodiment of the present invention may have a “1” state and a “0” state by using the high conductance state and the low conductance state of the thyristor, respectively.

Each of the memory cells MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal-based material or a semiconductor material. The second contact node SNC may include a metal-based material or a semiconductor material. For example, the first and second contact nodes BLC and SNC may include titanium, titanium nitride, tungsten, or a combination thereof. Also, the first and second contact nodes BLC and SNC may include doped polysilicon, and the first doped region SR and the second doped region DR may include impurities diffused from the first contact node BLC and the second contact node SNC, respectively.

The first capping layer BC may be disposed between the second conductive line DWL and the first conductive line BL. A second capping layer CC may be disposed between the second conductive line DWL and the first electrode SN of the data storage element CAP. The first capping layer BC may be disposed between the upper horizontal line G1 and the first conductive line BL, and the first capping layer BC may be disposed between the lower horizontal line G2 and the first conductive line BL. The second capping layer CC may be disposed between the upper horizontal line G1 and the first electrode SN of the data storage element CAP, and also the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may include a dielectric material. The first and second capping layers BC and CC may include silicon oxide, silicon nitride, silicon carbon oxide, an air gap, or a combination thereof. The first capping layer BC may include silicon oxide, and the second capping layer CC may include a stack of silicon oxide and silicon nitride.

Cell dielectric layers IL may be disposed between the memory cells MC that are stacked in the first direction D1. The second electrodes PN of the neighboring data storage elements CAP in the first direction D1 may be coupled to each other.

A plurality of first passivation layers BF1 may be disposed between the lowermost second conductive line DWL among the second conductive lines DWL and the lower structure LS. A second passivation layer BF2 may be disposed between the first conductive line BL and the lower structure LS. Third passivation layers BF3 may be disposed between the data storage element CAP and the lower structure LS. The first to third passivation layers BF1, BF2, and BF3 may include a dielectric material. The first to third passivation layers BF1, BF2, and BF3 may include silicon oxide. The first conductive line BL, the second conductive lines DWL, and the data storage elements CAP may be electrically disconnected from the lower structure LS by the first to third passivation layers BF1, BF2, and BF3, respectively. The first to third passivation layers BF1, BF2, and BF3 may also be referred to as bottom dielectric layers or bottom passivation layers. A lowermost-level inter-cell dielectric layer LIL may be disposed between the first passivation layers BF2 and the data storage element CAP.

The lower structure LS may include a semiconductor substrate, a metal interconnection structure, a dielectric structure, a conductive structure, a bonding pad structure, another memory, or a peripheral circuit portion.

For example, the lower structure LS may include a structure in which a peripheral circuit portion, a metal interconnection structure, and a bonding pad structure are stacked sequentially in the recited order. The memory cell array MCA and the peripheral circuit portion of the lower structure LS may be coupled by wafer bonding.

The peripheral circuit portion of the lower structure LS may be disposed at a lower level than the memory cell array MCA. This may also be referred to as COP (Cell-Over-Peripheral) structure. The peripheral circuit portion may include at least one control circuit for driving the memory cell array MCA. The at least one control circuit of the peripheral circuit portion may include an N-channel transistor, a P-channel transistor, a CMOS circuit, or a combination thereof. The at least one control circuit of the peripheral circuit portion may include an address decoder circuit, a read circuit, a write circuit, and the like. The at least one control circuit of the peripheral circuit portion may include a planar channel transistor, a recess channel transistor, a buried gate transistor, a fin channel transistor (FinFET), and the like.

For example, the peripheral circuit portion may include sub-word line drivers and a sense amplifier. The first conductive line BL may be coupled to the sense amplifier, and the second conductive lines DWL may be coupled to the sub-word line drivers.

According to another embodiment of the present invention, the peripheral circuit may include a first peripheral circuit including a selector structure BLS, a second peripheral circuit including sub-word line drivers, and a third peripheral circuit including a sense amplifier. The first peripheral circuit may be disposed at a higher level than the memory cell array MCA, and the second peripheral circuit and the third peripheral circuit may be disposed at a higher level than the second peripheral circuit. The second peripheral circuit and the third peripheral circuit may be arranged at the same level. The second peripheral circuit and the third peripheral circuit may be coupled to the memory cell array MCA and the selector structure BLS by wafer bonding using bonding pads.

According to another embodiment of the present invention, the memory cell array MCA may be disposed at a higher level than the selector structure BLS. For example, the backside of the lower structure LS may be disposed at the top, and accordingly, the selector structure BLS, the memory cell array MCA, and the lower structure LS may be arranged in the mentioned order.

According to another embodiment of the present invention, the peripheral circuit portion may be disposed at a higher level than the memory cell array MCA. This may also be referred to as POC (Peripheral-Over-Cell) structure. In this case, the peripheral circuit portion may be disposed at a higher level than the selector structure BLS.

According to another embodiment of the present invention, the memory cell array MCA may include a Dynamic Random Access Memory (DRAM), an embedded DRAM, NAND, a ferroelectric RAM (FeRAM), a Spin Torque Transfer RAM (STTRAM), a Phase-Change RAM (PCRAM), or a Resistive RAM (ReRAM).

The selector structure BLS may be coupled to the first conductive lines BL of the memory cell array MCA. The selector structure BLS may be an element for selecting the first conductive lines BL. For example, the first conductive line BL that is used may be turned on and used, and the other first conductive lines BL may be turned off. Accordingly, sufficient sensing margin may be secured in the memory cell array MCA of a multi-layer stack.

The selector structure BLS may use a multi-cell structure. For example, the selector structure BLS may include at least four select transistors STRs. The multi-cell structure refers to a plurality of select transistors STR and a selector CP. The selector CP may be commonly coupled to select transistors (select transistors, STR). The select transistors STR may also be referred to as ‘selector-level switching elements’.

The selector structure BLS may include a select transistor array STA and a selector (select-level plug, CP). The select transistor array STA may include a plurality of select transistors STR. The select transistors STR may have the same structure as that of the switching element TR of a memory cell MC. The select transistors STR that are stacked in the first direction D1 may share one selector CP.

The selector structure BLS may include a plurality of select transistors STR vertically stacked in the first direction D1. The selector structure BLS may include a plurality of selector-level horizontal conductive lines SDWL vertically stacked in the first direction D1. The selector structure BLS may include a plurality of selector-level horizontal layers SHL vertically stacked in the first direction D1. The selector structure BLS and the memory cell array MCA may share the first conductive line BL and the first contact node BLC. The selector structure BLS and the memory cell array MCA may share the dielectric layer DE and the second electrode PN of the data storage element CAP. The dielectric layer of the selector structure BLS may be simply referred to as ‘a selector-level dielectric layer SDE’, and the second electrode of the selector structure BLS may be simply referred to as ‘a selector level plate SPN’.

Each select transistor STR may include a selector-level horizontal conductive line SDWL and a selector-level horizontal layer SHL.

The selector-level horizontal conductive line SDWL may extend along its longitudinal axis in the third direction D3, and the selector-level horizontal layer SHL may extend along its longitudinal axis in the second direction D2. The selector-level horizontal layer SHL may be arranged horizontally from the first conductive line BL. The selector-level horizontal conductive line SDWL may have a double structure.

For example, the selector-level horizontal conductive line SDWL may include a selector-level upper horizontal line G11 and a selector-level lower horizontal line G12 that are facing each other with the selector-level horizontal layer SHL interposed between them. A selector-level inter-level dielectric layer SGD may be formed on the upper and lower surfaces of the selector-level horizontal layer SHL. The selector-level upper horizontal line G11 may be disposed over the selector-level horizontal layer SHL, and the selector-level lower horizontal line G12 may be disposed below the selector-level horizontal layer SHL. The selector-level horizontal conductive line SDWL may include a pair of a selector-level upper horizontal line G11 and a selector-level lower horizontal line G12. In the selector-level horizontal conductive line SDWL, the same driving voltage may be applied to the selector-level upper horizontal line G11 and the selector-level lower horizontal line G12. The selector-level horizontal conductive lines SDWL may also be referred to as selector-level horizontal word lines or selector-level horizontal gates.

The second conductive line DWL and the selector-level horizontal conductive line SDWL may include the same structure and the same material.

The selector-level horizontal layer SHL may extend in the second direction D2. The selector-level horizontal layer SHL may include a semiconductor material. For example, the selector-level horizontal layer SHL may include polysilicon, monocrystalline silicon, germanium, or silicon-germanium. According to another embodiment of the present invention, the selector-level horizontal layer SHL may include an oxide semiconductor material. For example, the oxide semiconductor material may include Indium Gallium Zinc Oxide (IGZO). The selector-level horizontal layer SHL and the horizontal layer HL may include the same material. The horizontal length of the selector-level horizontal layer SHL may be greater than the horizontal length of the horizontal layer HL. For example, when the horizontal lengths in the second direction D2 are compared, the horizontal length of the selector-level horizontal layer SHL may be greater than the horizontal length of the horizontal layer HL. The horizontal layer HL may also be referred to as a ‘cell level horizontal layer’.

The upper and lower surfaces of the selector-level horizontal layer SHL may have a flat surface. The upper and lower surfaces of the selector-level horizontal layer SHL may be parallel to each other in the second direction D2.

The selector-level horizontal layer SHL may include a selector-level channel SCH, a selector-level first doped region SSR disposed between the selector-level channel SCH and the first conductive line BL, and a selector-level second doped region SDR disposed between the selector-level channel SCH and the selector CP. When the selector-level horizontal layer SHL is formed of an oxide semiconductor material, the selector-level channel SCH may be formed of an oxide semiconductor material, and the selector-level first and second doped regions SSR and SDR may be omitted. The selector-level horizontal layer SHL may also be referred to as an active layer or a thin-body.

The selector-level first doped region SSR and the selector-level second doped region SDR may be doped with impurities of the same conductivity type. The selector-level first doped region SSR and the selector-level second doped region SDR may be doped with an N-type impurity or P-type impurity. The selector-level first doped region SSR and the selector-level second doped region SDR may include at least one impurity selected from arsenic (As), phosphorus (P), boron (B), indium (In), and combinations thereof. The selector-level first doped region SSR may be coupled to the first conductive line BL, and the selector-level second doped region SDR may be coupled to the selector CP. The selector-level first doped regions SSR of the select transistors STR that are stacked in the first direction D1 may be commonly coupled to the first conductive line BL. The selector-level second doped regions SDR of the select transistors STR that are stacked in the first direction D1 may be commonly coupled to the selector CP. The selector CP may have a pillar shape that passes through the selector-level second doped regions SDR of the select transistors STR that are stacked in the first direction D1. The memory cell array MCA and the selector structure BLS may share the first conductive line BL. The first conductive line BL may be a common conductive line.

The selector-level inter-level dielectric layer SGD may include silicon oxide, silicon nitride, a metal oxide, a metal oxynitride, a metal silicate, a high-k material, a ferroelectric material, an anti-ferroelectric material, or a combination thereof. The selector-level inter-level dielectric layer SGD may include SiO₂, Si₃N₄, HfO₂, Al₂O₃, ZrO₂, AlON, HfON, HfSiO, HfSiON, HfZrO, or a combination thereof.

The selector-level inter-level dielectric layer SGD may be disposed over a first surface (or an upper surface) and a second surface (or a lower surface) of the selector-level horizontal layer SHL. The first and second surfaces of the selector-level horizontal layer SHL may be flat surfaces.

The selector-level horizontal conductive line SDWL may include a metal-based material, a semiconductor material, or a combination thereof. The selector-level horizontal conductive line SDWL may include titanium nitride, tungsten, polysilicon, or a combination thereof. For example, the selector-level horizontal conductive line SDWL may include a TiN/W stack in which titanium nitride and tungsten are sequentially stacked. The selector-level horizontal conductive line SDWL may include an N-type work function material or a P-type work function material. The N-type work function material may have a low work function of approximately 4.5 eV or less, and the P-type work function material may have a high work function of approximately 4.5 eV or more. The selector-level horizontal conductive line SDWL may include a stack of a low work function material and a high work function material.

As described above, the select transistors STR and the switching elements TR may be formed in the same structure, and the horizontal layers HL and the selector-level horizontal layers SHL may have different horizontal lengths.

The selectors CP may include a conductive material. Selectors CP may include a semiconductor material, a metal-based material, or a combination thereof. The selectors CP may include doped polysilicon. The selectors CP may include a metal silicide, a metal nitride, a metal, or a combination thereof. The selectors CP may include a stack of TiSi₂/TiN/W. The selector-level second doped regions SDR may include impurities diffused from the selectors CP. The selector-level first doped regions SSR may include impurities diffused from the first contact node BLC. The selectors CP may be hole-shaped pillars. The selectors CP may also be referred to as ‘conductive pillar structures’. From the perspective of a top view, the cross-section of the selectors CP may be a square shape, a circular shape, an oval shape or a polygonal shape. The selectors CP may be used collectively on the basis of a unit of a cell mat. For example, a memory device may include a plurality of memory banks that are arranged in a matrix structure, and each memory bank may include a plurality of cell mats.

Each cell mat may include a plurality of memory cells MC. The selectors CP may also be referred to as selector-level plugs. The selectors CP may be disposed between the selector-level horizontal conductive line SDWL and the selector level plate SPN.

A plurality of selector-level horizontal layers SHL and one first conductive line BL may be electrically connected to one selector CP. Accordingly, one selector CP may select one first conductive line BL among the first conductive lines BL of the memory cell array MCA.

A plurality of liner layers L1 and L2 may be disposed between the selector-level horizontal conductive line SDWL and the selector level plate SPN, and a spacer L3 may be disposed between the liner layers L1 and L2 and the selector level plate SPN. The liner layers L1 and L2 and the spacer L3 may include a dielectric material. The selectors CP may penetrate the liner layers L1 and L2 and the selector-level horizontal layer SHL.

The semiconductor device 100 may further include metal interconnections ML. The metal interconnections ML may be coupled to the first conductive line BL and the selectors CP, respectively. The second top dielectric layer HM2 may be disposed over the first top dielectric layer HM1, and the metal interconnections ML may penetrate the second top dielectric layer HM2. The first and second top dielectric layers HM1 and HM2 may also be referred to as an inter-layer dielectric layer. When the first conductive line BL includes a bit line, the first conductive line BL may be coupled to the sense amplifier through the metal interconnections ML.

Referring to FIGS. 1A to 3, the semiconductor device 100 may include a 3D DRAM, and the memory cell array MCA may include a memory cell array of the DRAM, and the selector structure BLS may include a bit line selector. The first conductive line BL may include a bit line, and the data storage element CAP may include a capacitor. The switching element TR may include a cell transistor. From another perspective, the semiconductor device 100 may include a memory cell array MCA including the bit line BL that extends vertically from the upper portion of the lower structure LS and a plurality of horizontal layers HL that are stacked vertically while sharing the bit line BL, and a selector structure BLS disposed at a higher level than the memory cell array MCA. The selector structure BLS may include a plurality of select transistors STR vertically stacked and a bit line selector CP that is commonly coupled to the select transistors STR.

According to the above description, by forming the selector structure BLS of a multi-cell structure, the first vertical conductive line capacitance Cb may be reduced. Accordingly, sufficient sensing margin may be secured even in a higher stack structure of a three-dimensional memory cell MC.

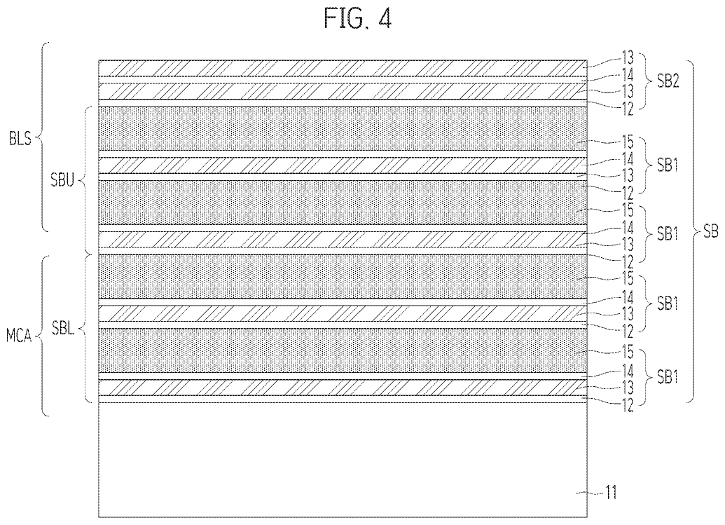

FIGS. 4 to 29 are plan view schematics illustrating a method for fabricating the semiconductor devices in accordance with embodiments of the present invention.

Referring to FIG. 4, an etch target layer may be formed over the lower structure 11. The lower structure 11 may be made of or include a material suitable for semiconductor processing. The lower structure 11 may include at least one of a conductive material, a dielectric material, and a semiconductive material. Diverse materials may be formed over the lower structure 11. The lower structure 11 may include a semiconductor substrate. The lower structure 11 may be formed of a material containing silicon. The lower structure 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The lower structure 11 may also include other semiconductor materials, such as germanium. The lower structure 11 may include a III/V-group semiconductor substrate, for example, a compound semiconductor substrate, such as GaAs. The lower structure 11 may include a Silicon-On-Insulator (SOI) substrate.

The etch target layer may include a stack body SB. The stack body SB may include a plurality of sub-stacks SB1 that are stacked several times. Each of the sub-stacks SB1 may include a first layer 12, a second layer 13, a third layer 14, and a fourth layer 15 that are stacked sequentially in the recited order. The first layers 12 and the third layers 14 may include the same material, and the first layers 12 and the third layers 14 may include silicon germanium or monocrystalline silicon germanium. The second layers 13 and the fourth layers 15 may be the same material and may include monocrystalline silicon. The first layers 12, the second layers 13, the third layers 14, and the fourth layers 15 may be formed by an epitaxial growth process. The lowermost-level first layer 12 may serve as a seed layer during the epitaxial growth process. The first layers 12 and the third layers 14 may be thinner than the second layers 13, and the fourth layers 15 may be thicker than the second layers 13.

As illustrated in the above-described embodiments of the present invention, when memory cells are stacked, the stack body SB may be formed by stacking the sub-stacks SB1 several times. A hard mask level sub-stack SB2 may be disposed on top of the stack body SB. The hard mask level sub-stack SB2 may include the first layer 12, the second layer 13, the third layer 14, and the second layer 13 that are stacked sequentially in the recited order.

Each of the sub-stacks SB1 may be a four-layer stack of the first layer 12/second layer 13/third layer 14/fourth layer 15. For example, when the first layers 12 and the third layers 14 include a silicon germanium layer and the second and the fourth layers 13, and 15 include a monocrystalline silicon layer, each of the sub-stacks SB1 may include a stack of the first silicon germanium/first monocrystalline silicon/second silicon germanium/second monocrystalline silicon (SiGe/Si/SiGe/Si). The second monocrystalline silicon layers may be thicker than the first monocrystalline silicon layers.

The first layers 12, the second layers 13, and the third layers 14 may also be referred to as ‘sacrificial layers’, and the fourth layers 15 may also be referred to as recess target layers. The stack body SB may also be referred to as a vertical stack. The stack body SB may be formed by alternating a plurality of sacrificial layers and a plurality of recess target layers. The sacrificial layers may include the first layers 12, the second layers 13 and the third layers 14, and the recess target layers may include the fourth layers 15. Each of the sacrificial layers may include a three-layer stack of a first silicon germanium layer/first monocrystalline silicon layer/second silicon germanium layer, and each of the recess target layers may include a single layer of a second monocrystalline silicon layer, and the second monocrystalline silicon layers may be thicker than the first monocrystalline silicon layers.

The stack body SB may include a lower-level stack body SBL disposed over the lower structure 11, and an upper-level stack body SBU disposed over the lower-level stack body SBL. Each of the lower-level stack body SBL and the upper-level stack body SBU may include a plurality of sub-stacks SB1. The lower-level stack body SBL may be an area where the memory cell array MCA is to be formed, and the upper-level stack body SBU may be an area where the selector BLS is to be formed. The hard mask level sub-stack SB2 may be disposed over the upper-level stack body SBU. Hereinafter, the reference symbol ‘MCA’ may be simply referred to as a memory cell array region, and the reference symbol ‘BLS’ may be simply referred to as a selector region.

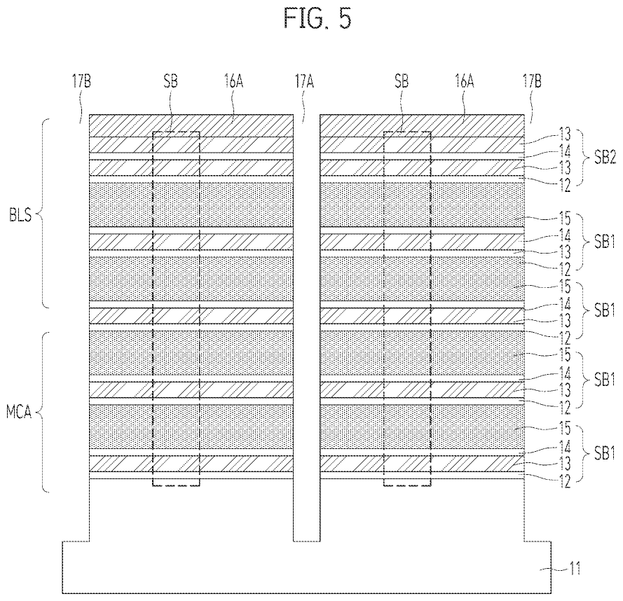

Referring to FIG. 5, a hard mask pattern 16A may be formed over the stack body SB. The hard mask pattern 16A may be formed to be in direct contact with the stack body SB. The hard mask level sub-stack SB2 and the sub-stacks SB1 of the stack body SB may be etched by using the hard mask pattern 16A as an etch barrier. As a result, a plurality of sacrificial vertical openings 17A and 17B may be formed. The sacrificial vertical openings 17A and 17A may include first sacrificial vertical openings 17A and second sacrificial vertical openings 17B. The first and second sacrificial vertical openings 17A and 17B may have the same size. The first and second sacrificial vertical openings 17A and 17B may pass through the stack body SB and extend into the lower structure 11. From the perspective of a top view, the first and second sacrificial vertical openings 17A and 17B may be hole-shaped openings. The cross-section of the first and second sacrificial vertical openings 17A and 17B may be a square shape, a circular shape, or an oval shape. The hard mask pattern 16A may have an etch selectivity with respect to the stack body SB. The hard mask pattern 16A may include silicon nitride, silicon oxide, amorphous carbon, a photoresist, or a combination thereof.

The first and second sacrificial vertical openings 17A and 17B may be formed simultaneously in the selector region BLS and the memory cell array region MCA.

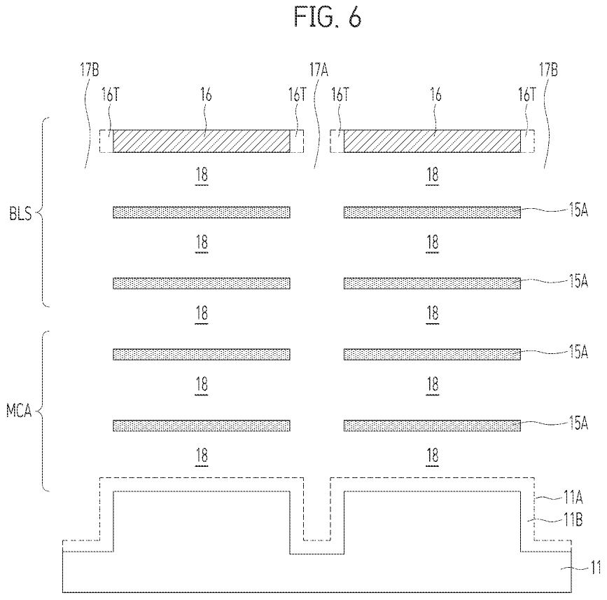

Referring to FIG. 6, both side surfaces of the hard mask patterns 16A may be trimmed (see a reference numeral ‘16T’). Subsequently, using the trimmed hard mask pattern 16 as a barrier, the first and third layers 12 and 14 may be selectively removed through the first and second sacrificial vertical openings 17A and 17B. To selectively remove the first and the third layers 12 and 14, the difference between the etch selectivity of the second and fourth layers 13 and 15 and the etch selectivity of the first and third layers 12 and 14 may be used. The first layers 12 and the third layers 14 may be removed using a wet etching process or a dry etching process. For example, when the first layers 12 and the third layers 14 include a silicon germanium layer and the second and the fourth layers 13, and 15 include a monocrystalline silicon layer, the silicon germanium layers may be etched by using an etchant or an etchant gas having a selectivity for the silicon germanium layers while leaving the monocrystalline silicon layers intact.

Subsequently, the second and the fourth layers 13, and 15 may be recessed. To recess the second and the fourth layers 13, and 15, a wet etching process or a dry etching process may be performed.

According to this embodiment of the present invention, the fourth layers 15 may be partially etched while the second layers 13 are removed. As a result, the second layers 13 may be removed, and the fourth layers 15 may become thin, as indicated by a reference numeral ‘15A’. The recess process for forming the thin fourth layer 15A, that is, the preliminary horizontal layers 15A, may also be referred to as a thinning process or a trimming process of the fourth layers 15. To form the preliminary horizontal layers 15A, the upper (i.e., top) surface, lower (i.e., bottom) surface, and side (also lateral) surfaces of the fourth layers 15 may be recessed. The preliminary horizontal layers 15A may also be referred to as thin-body active layers. The preliminary horizontal layers 15A may include a monocrystalline silicon layer. The recess process for forming the preliminary horizontal layers 15A may use, for example, HSC1 (Hot SC-1). HSC1 may include a solution of ammonium hydroxide (NH₄OH), hydrogen peroxide (H₂O₂), and water (H₂O) that are mixed at a weight ratio of approximately 1:4:20. The second layers 13 and the fourth layers 15 may be selectively etched by using HSC1.

The preliminary horizontal layers 15A may be formed by a recess process for the fourth layers 15 as described above, and horizontal recesses 18 may be formed between the vertically stacked preliminary horizontal layers 15A. Each of the upper and lower surfaces of the preliminary horizontal layers 15A may include a flat surface.

From the perspective of a top view, the preliminary horizontal layers 15A may have a cross shape, and the side surfaces of the preliminary horizontal layers 15A may have a bent shape or a round shape.

After the preliminary horizontal layers 15A are formed, the depth and width of the first and second sacrificial vertical openings 17A and 17B may be expanded. While the preliminary horizontal layers 15A are formed, the surface 11A of the lower structure 11 may be recessed to a predetermined depth (see a reference numeral ‘11B’). As a result, the depths of the first and second sacrificial vertical openings 17A and 17B may increase.

The preliminary horizontal layers 15A may be formed in the selector region BLS and the memory cell array region MCA. According to another embodiment of the present invention, the number of preliminary horizontal layers 15A formed in the memory cell array region MCA may be greater than the number of preliminary horizontal layers 15A formed in the selector region BLS.

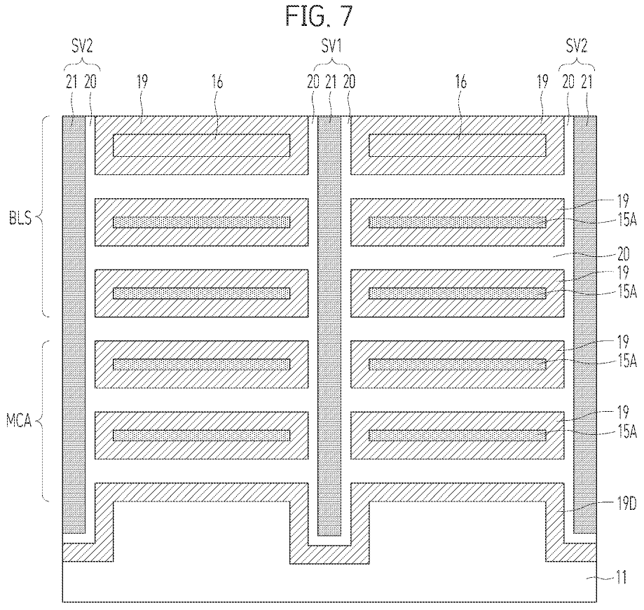

Referring to FIG. 7, first dielectric layers 19 surrounding the preliminary horizontal layers 15A may be formed. The first dielectric layers 19 may include silicon nitride. The first dielectric layers 19 may fully cover the upper surface, lower surface, and side surfaces of the preliminary horizontal layers 15A.

While the first dielectric layers 19 are formed, a dummy dielectric layer 19D may be formed on the surface of the lower structure 11. First dielectric layers 19 may also form to fully surround the hard mask layer pattern 16, i.e., may cover the upper surface, lower surface, and side surfaces of the hard mask layer pattern 16.

Subsequently, a second dielectric layer 20 may be formed over the first dielectric layers 19. The second dielectric layer 20 may be formed on the first dielectric layers 19 and be in direct contact with the first dielectric layers 19. The second dielectric layer 20 may fill a space between the vertically neighboring first dielectric layers 19. The second dielectric layer 20 may include silicon oxide. Portions of the second dielectric layer 20 may be conformally formed on the surfaces of the first and second sacrificial vertical openings 17A and 17B. The horizontal recesses (see reference numeral 18 in FIG. 6) may be filled with the first dielectric layer 19 and the second dielectric layer 20.

Subsequently, a sacrificial gap-fill layer 21 may be formed over the second dielectric layer 20 which is disposed in the first and second sacrificial vertical openings 17A and 17B. The sacrificial gap-fill layer 21 may be a sacrificial material and may include amorphous carbon. According to another embodiment of the present invention, a pillar capping layer may be further formed over the sacrificial gap-fill layer 21. The pillar capping layer may include a metal-based material. The pillar capping layer may include titanium nitride. Forming the sacrificial gap-fill layer 21 may include depositing a sacrificial material and planarizing the sacrificial material. The planarization process for forming the sacrificial gap-fill layer 21 may be performed until the uppermost-level first dielectric layer 19 is exposed. Subsequently, the uppermost-level second dielectric layers 20 may also be planarized until the uppermost-level first dielectric layer 19 is exposed. As shown in FIG. 7, the sacrificial gap-fill layer 21 is not formed between the vertically stacked first dielectric layers 19.

The second dielectric layer 20 and the sacrificial gap-fill layer 21 may form first and second sacrificial pillar structures SV1 and SV2 that fill the first and second sacrificial vertical openings 17A and 17B, respectively. Accordingly, the first sacrificial pillar structure SV1 may fill the first sacrificial vertical openings 17A, and the second sacrificial pillar structure SV2 may fill the second sacrificial vertical openings 17B respectively. According to another embodiment of the present invention, the first and second sacrificial pillar structures SV1 and SV2 may include a dielectric material, a carbon-containing material, a metal-based material, or a combination thereof. According to another embodiment of the present invention, the first and second sacrificial pillar structures SV1 and SV2 may include silicon oxide, silicon nitride, titanium nitride, amorphous carbon, or a combination thereof. From the perspective of a top view, the first sacrificial pillar structure SV1 and the second sacrificial pillar structure SV2 may be hole-shaped sacrificial pillars. According to another embodiment of the present invention, portions of the first dielectric layer 19 may be conformally formed on the surfaces of the first and second sacrificial vertical openings 17A and 17B. As a result, the first and second sacrificial pillar structures SV1 and SV2 may further include portions of the first dielectric layer 19.

As described above, as the preliminary horizontal layers 15A, the first dielectric layers 19, and the second dielectric layers 20 are formed, a cell mold structure may be formed. The cell mold structure may include a plurality of cell molds. Each of the cell molds may include a plurality of mold layers. The mold layers refers to the preliminary horizontal layers 15A, the first dielectric layers 19, and the second dielectric layers 20. Each of the cell molds may include an ONSN (Oxide-Nitride-Silicon-Nitride) stack. The ONSN stack refers to a structure in which silicon oxide, a first silicon nitride, a monocrystalline silicon layer, and a second silicon nitride are sequentially stacked. The silicon oxide may correspond to the second dielectric layers 20, the first and second silicon nitrides may correspond to the first dielectric layers 19, and the monocrystalline silicon layer may correspond to the preliminary horizontal layers 15A. A cell mold structure including a plurality of cell molds may also be referred to as a vertical stack. From another perspective, the cell mold structure may include an ONSNO (Oxide-Nitride-Silicon-Nitride-Oxide) stack. The ONSNO stack refers to a structure in which a first silicon oxide, a first silicon nitride, a monocrystalline silicon layer, a second silicon nitride, and a second silicon oxide are sequentially stacked.

As described above, the sub-stacks SB1 of the stack body SB may be replaced with cell molds through a series of the processes according to FIGS. 4 to 7. The first layers 12, the second layers 13, and the third layers 14 may be replaced with the first dielectric layers 19 and the second dielectric layers 20. The fourth layers 15 may become the preliminary horizontal layers 15A through a recess process. The first dielectric layers 19 may also be referred to as trimming target layers.

According to another embodiment of the present invention, a trimming process may be performed onto the first dielectric layers 19. For example, from the perspective of a top view, the first dielectric layers 19 may be trimmed to form a cross-shaped pattern.

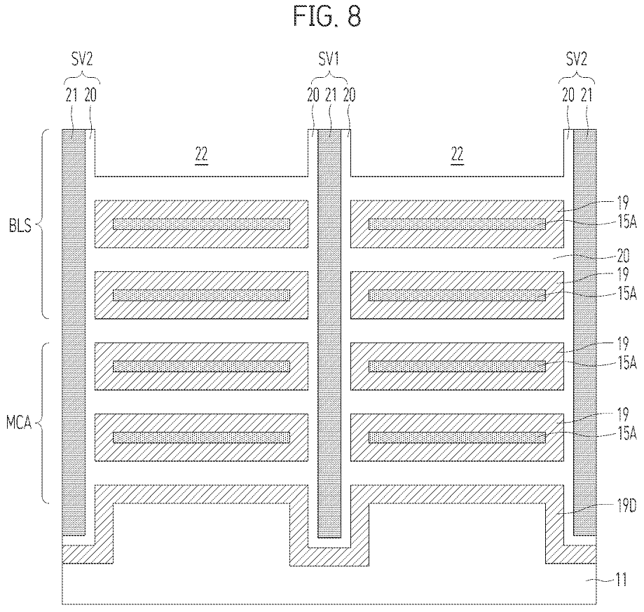

Referring to FIG. 8, the hard mask pattern 16 and the uppermost-level first dielectric layer 19 may be removed to form the hard mask layer level recess 22. The hard mask layer level recess 22 may be formed in the selector region BLS.

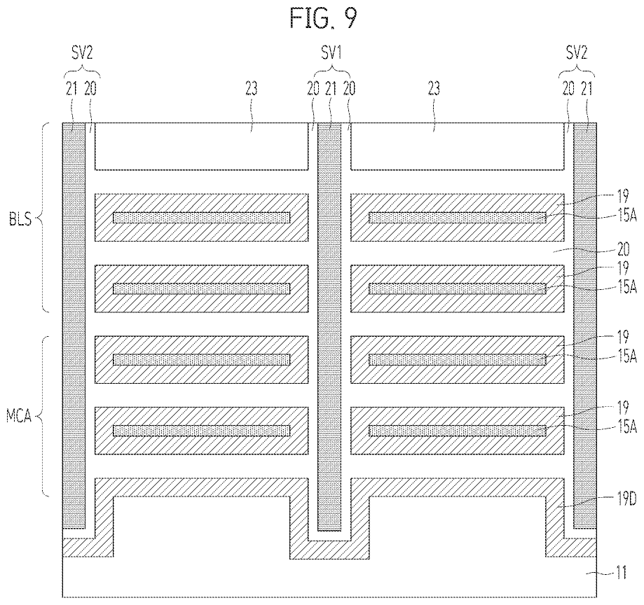

Referring to FIG. 9, a top dielectric layer 23 that fills the hard mask layer level recess 22 may be formed. The top dielectric layer 23 may include silicon oxide.

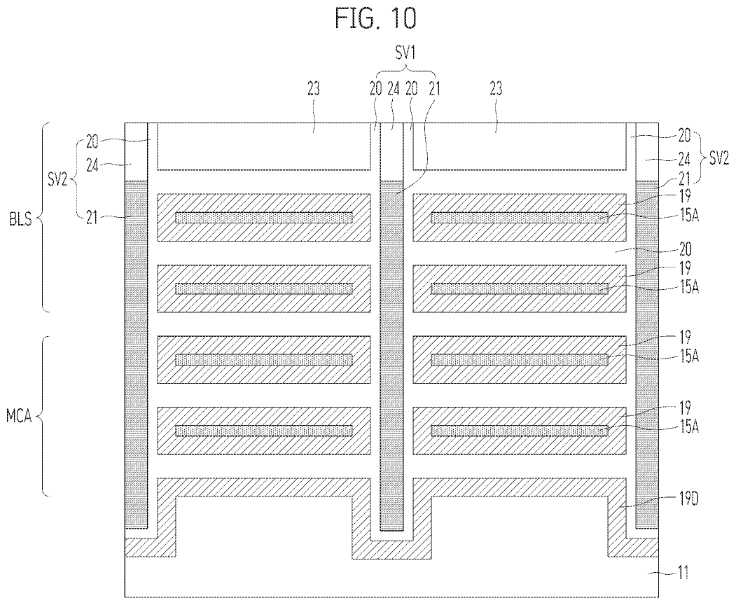

Referring to FIG. 10, the upper end portion of the sacrificial gap-fill layer 21 may be replaced with a top-level sacrificial pillar 24. The top-level sacrificial pillar 24 may include silicon oxide. Forming the top-level sacrificial pillar 24 may include recessing an upper portion of the sacrificial gap-fill layer 21 and filling the recessed upper portion of the sacrificial gap-fill layer 21 with a sacrificial material.

The first and second sacrificial pillar structures SV1 and SV2 may include the second dielectric layer 20, the sacrificial gap-fill layer 21, and the top-level sacrificial pillar 24.

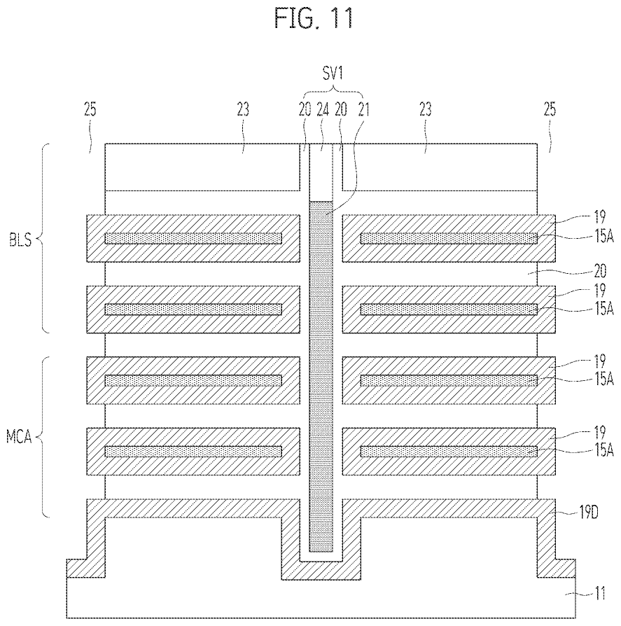

Referring to FIG. 11, initial vertical openings 25 may be formed by removing the second sacrificial pillar structures SV2. The initial vertical openings 25 may be hole-shaped openings.

Subsequently, the second dielectric layer 20 may be selectively recessed. As a result, first side surfaces of the first dielectric layers 19 and the dummy dielectric layers 19D may be exposed.

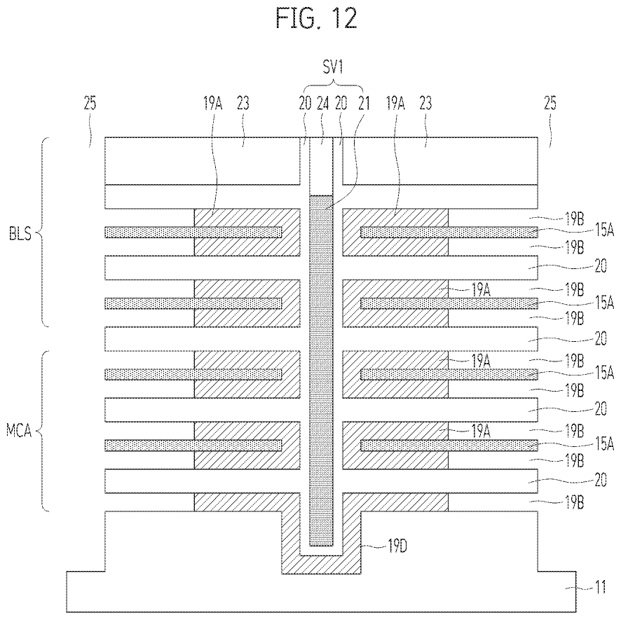

Referring to FIG. 12, the first dielectric layers 19 and the dummy dielectric layer 19D may be selectively horizontally recessed from the initial vertical openings 25. As a result, first dielectric layer patterns 19A and dielectric layer level recesses 19B may be formed. Portions of the preliminary horizontal layers 15A may be exposed by the dielectric layer level recesses 19B. From the perspective of a top view, the first dielectric layer patterns 19A may have a cross shape.

The first dielectric layer patterns 19A and the dielectric layer level recesses 19B may be formed in the selector region BLS and the memory cell array region MCA.

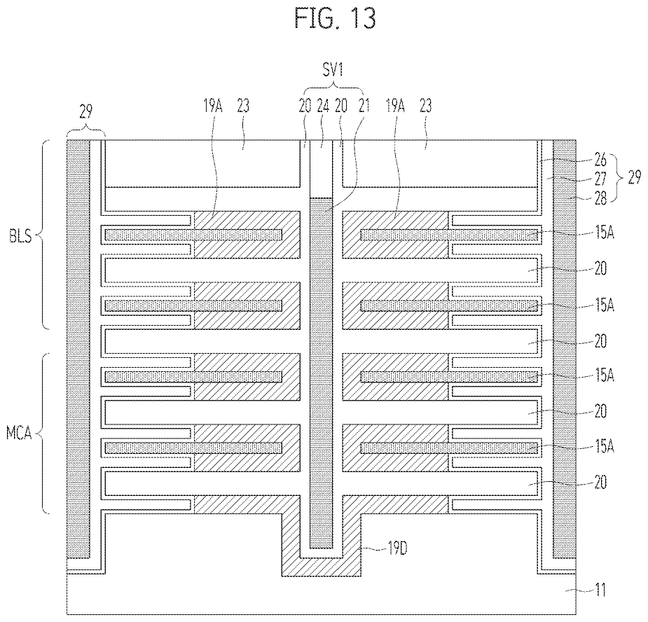

Referring to FIG. 13, vertical sacrificial structures 29 may be formed to fill the dielectric layer level recesses 19B. The vertical sacrificial structures 29 may include a stack of a first liner layer 26, a second liner layer 27, and a gap-fill layer 28. The first liner layer 26 may include silicon oxide, and the second liner layer 27 may include silicon nitride. The gap-fill layer 28 may include amorphous carbon, titanium nitride, or a combination thereof. The dielectric layer level recesses 19B may be filled with the first liner layer 26 and the second liner layer 27. A stack of the first liner layer 26, the second liner layer 27, and the gap-fill layer 28 may fill the initial vertical openings 25. The gap-fill layer 28 may not be formed in the dielectric layer level recesses 19B.

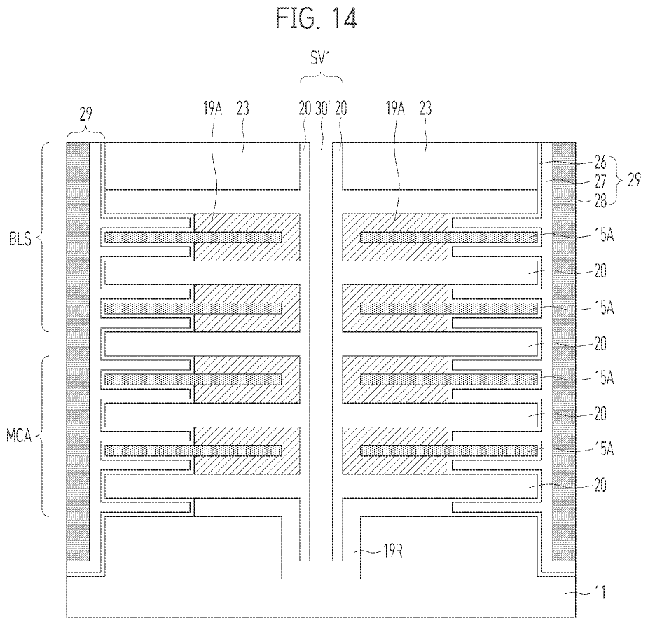

Referring to FIG. 14, the top-level sacrificial pillar 24 and the sacrificial gap-fill layer 21 may be selectively removed from the first sacrificial pillar structure SV1. As a result, a vertical level path 30′ may be formed.

Subsequently, the dummy dielectric layer 19D below the vertical level path 30′ may be removed to form the lower-level gap 19R.

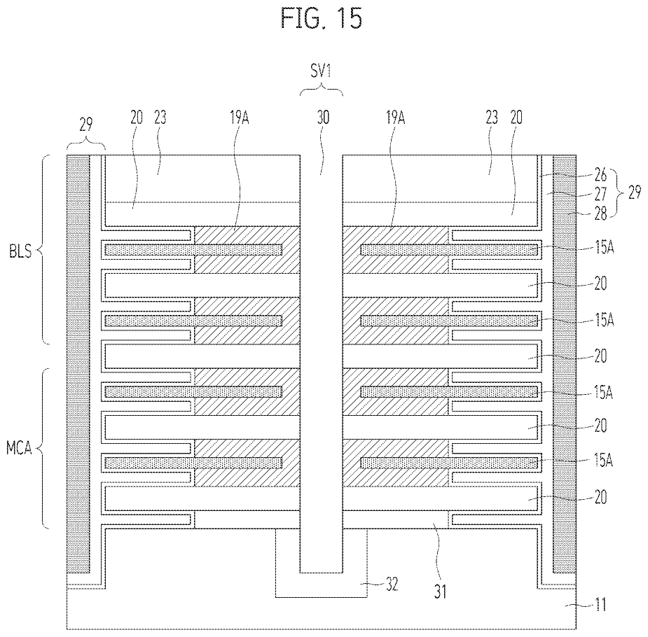

Referring to FIG. 15, in order to form first hole-shaped vertical openings 30, the second dielectric layers 20 may be cut through the vertical level path 30′. The first hole-shaped vertical openings 30 may be formed in the selector region BLS and the memory cell array region MCA.

Subsequently, a first passivation layer 31 may be formed to fill the lower-level gap 19R. The first passivation layer 31 may include silicon oxide. Forming the first passivation layer 31 may include depositing silicon oxide to fill the lower-level gap 19R and etching the silicon oxide. While the first passivation layer 31 is formed, the second dielectric layer 20 may be partially recessed.

Subsequently, a second passivation layer 32 may be formed in the lower region of the first hole-shaped vertical openings 30. For example, the surface of the lower structure 11 may be oxidized to form the second passivation layer 32.

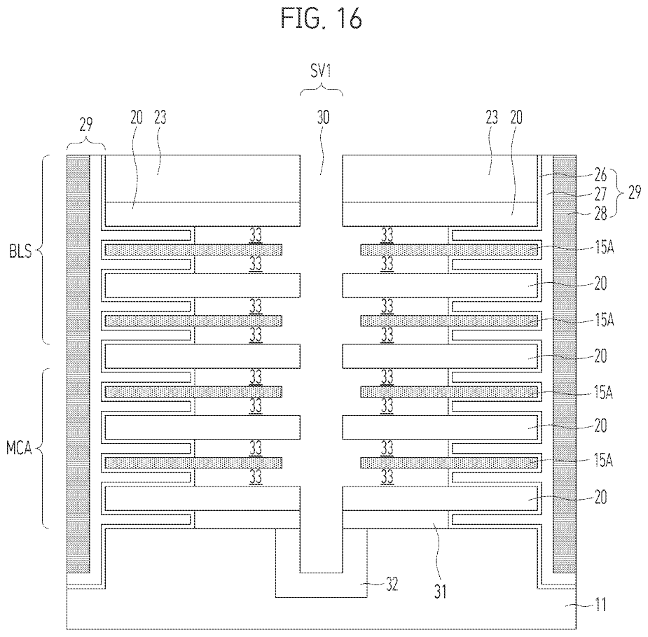

Referring to FIG. 16, to form horizontal level recesses 33, the first dielectric layer patterns 19A may be removed through the first hole-shaped vertical opening 30. From the perspective of a top view, the horizontal level recesses 33 may have a cross shape. Portions of the preliminary horizontal layers 15A may be exposed by the horizontal level recesses 33. The horizontal level recesses 33 may be disposed between the second dielectric layers 20 and the preliminary horizontal layers 15A. Two horizontal level recesses 33 may face each other with one preliminary horizontal layer 15A between them.

The horizontal level recesses 33 may be formed in the selector region BLS and the memory cell array region MCA.

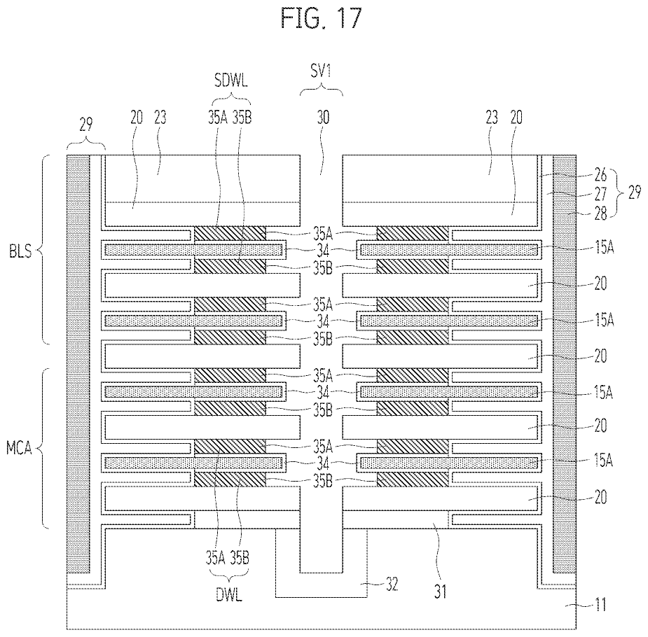

Referring to FIG. 17, an inter-level dielectric layer 34 may be formed over the exposed portions of the preliminary horizontal layers 15A. The inter-level dielectric layer 34 may also be referred to as a gate dielectric layer. The inter-level dielectric layer 34 may correspond to the inter-level dielectric layer GD as illustrated in FIG. 1.

The inter-level dielectric layer 34 may be formed by oxidizing the surfaces of the preliminary horizontal layers 15A. According to another embodiment of the present invention, the inter-level dielectric layer 34 may be formed by a deposition process of silicon oxide. The inter-level dielectric layer 34 may include silicon oxide, silicon nitride, a metal oxide, a metal oxynitride, a metal silicate, a high-k material, a ferroelectric material, an anti-ferroelectric material, or a combination thereof. The inter-level dielectric layer 34 may include SiO₂, Si₃N₄, HfO₂, Al₂O₃, ZrO₂, AlON, HfON, HfSiO, HfSiON, or a combination thereof.

Subsequently, a horizontal conductive line 35 that fills the horizontal level recesses 33 may be formed over the inter-level dielectric layer 34. Forming the horizontal conductive line 35 may include depositing a conductive material that fills the horizontal level recesses 33 over the inter-level dielectric layer 34 and performing an etch-back process onto the conductive material.

The horizontal conductive line 35 may include a pair of a first horizontal conductive line 35A and a second horizontal conductive line 35B that are facing each other with the preliminary horizontal layer 15A between them. The first and second horizontal conductive lines 35A and 35B may include a metal-based material, a semiconductor material, or a combination thereof. The first and second horizontal conductive lines 35A and 35B may include titanium nitride, tungsten, polysilicon, or a combination thereof. For example, the first and second horizontal conductive lines 35A and 35B may include a TiN/W stack in which titanium nitride and tungsten are sequentially stacked. The first and second horizontal conductive lines 35A and 35B may include an N-type work function material or a P-type work function material. The N-type work function material may have a low work function of approximately 4.5 eV or less, and the P-type work function material may have a high work function of approximately 4.5 eV or more.

The horizontal conductive line 35 may correspond to the second conductive line DWL as illustrated in FIGS. 1A to 3, and the first horizontal conductive line 35A and the second horizontal conductive line 35B may correspond to an upper horizontal line G1 and a lower horizontal line G2, respectively. As illustrated in FIG. 3, each of the first and second horizontal conductive lines 35A and 35B may have a cross shape and may include a channel overlapping portion WLP and a channel non-overlapping portion NOL.

A plurality of horizontal conductive lines DWL may be formed in the memory cell array region MCA. Selector-level horizontal conductive lines SDWL may be formed in the selector region BLS.

The selector-level horizontal conductive lines SDWL may have a double structure. For example, a selector-level horizontal conductive line SDWL may include a first horizontal conductive line 35A and a second horizontal conductive line 35B that are facing each other with the preliminary horizontal layer 15A interposed between them. The selector-level horizontal conductive line SDWL may include a pair of the first horizontal conductive line 35A and the second horizontal conductive line 35B. In the selector-level horizontal conductive line SDWL, the same driving voltage may be applied to the first horizontal conductive line 35A and the second horizontal conductive line 35B.

The selector-level horizontal conductive lines SDWL and the horizontal conductive lines DWL may have the same structure and may be formed of the same material.

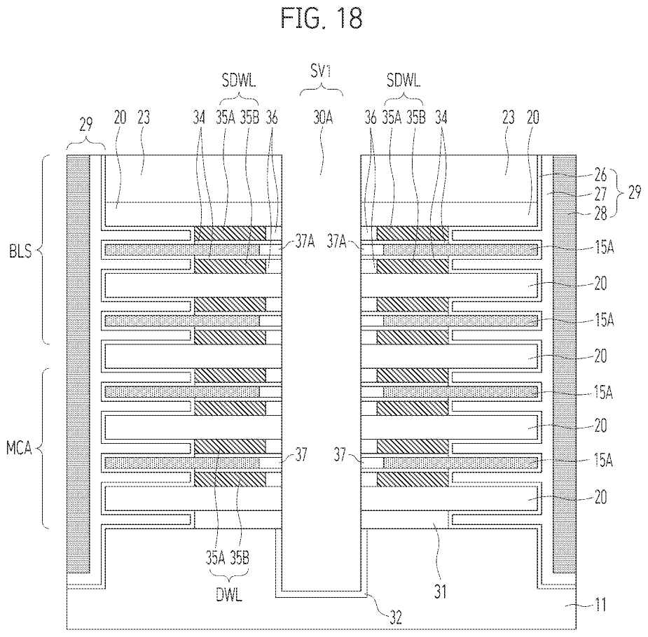

Referring to FIG. 18, first capping layers 36 may be formed on first side surfaces of the horizontal conductive lines 35. The first capping layers 36 may include silicon oxide, silicon nitride, silicon carbon oxide, an embedded air gap, or a combination thereof. Deposition of a capping material and an etch-back process may be performed to form the first capping layer 36. While the first capping layer 36 is formed, the first hole-shaped vertical opening may be expanded as indicated by ‘30A’. When the first capping layer 36 is formed or after the first capping layer 36 is formed, a portion of the inter-level dielectric layer 34 may be removed to expose a first edge portion of each of the preliminary horizontal layers 15A. When the first capping layer 36 is formed or after the first capping layer 36 is formed, a portion of the second passivation layer 32 may be etched.

Subsequently, a first doped region 37 may be formed in the first edge portion of each of the preliminary horizontal layers 15A. Forming the first doped region 37 may include depositing polysilicon that is doped with an N-type impurity, performing a heat treatment, and removing the doped polysilicon. The first doped region 37 may include an impurity that is diffused from the doped polysilicon. According to another embodiment of the present invention, the first doped region 37 may be formed by a process of doping an impurity.

A plurality of first doped regions 37 may be formed in the memory cell array region MCA. A selector-level first doped region 37A may be formed in the selector region BLS.

The first doped region 37 and the selector-level first doped region 37A may be formed simultaneously.

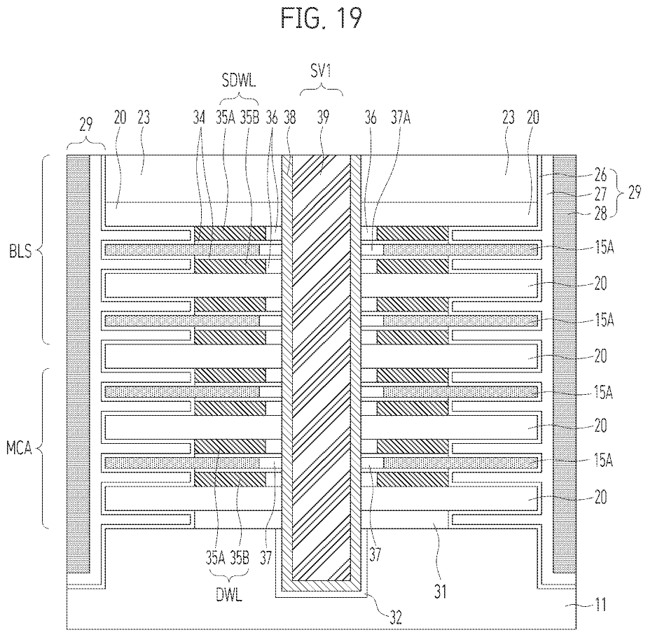

Referring to FIG. 19, a vertical conductive line 39 coupled to the first edge portion of each of the preliminary horizontal layers 15A may be formed. The vertical conductive line 39 may fill the first hole-shaped vertical openings 30A. The vertical conductive line 39 may be commonly coupled to the preliminary horizontal layers 15A. The vertical conductive line 39 may include titanium nitride, tungsten, or a combination thereof. The vertical conductive line 39 may also be referred to as a bit line or a vertical bit line.

Before the vertical conductive line 39 is formed, a first contact node 38 may be formed. The first contact node 38 may include doped polysilicon. The first doped region 37 may include an impurity which is diffused from the first contact node 38. After the first contact node 38 is formed, the impurity may be diffused from the first contact node 38 to form the first doped region 37. A metal silicide layer may be further formed between the vertical conductive line 39 and the first contact node 38.

The vertical conductive line 39 may correspond to the first conductive line BL as illustrated in FIGS. 1A to 3.

The vertical conductive line 39 may be formed in the selector region BLS and may extend vertically to be disposed in the memory cell array region MCA. The vertical conductive line 39 may be shared by the selector region BLS and the memory cell array region MCA.

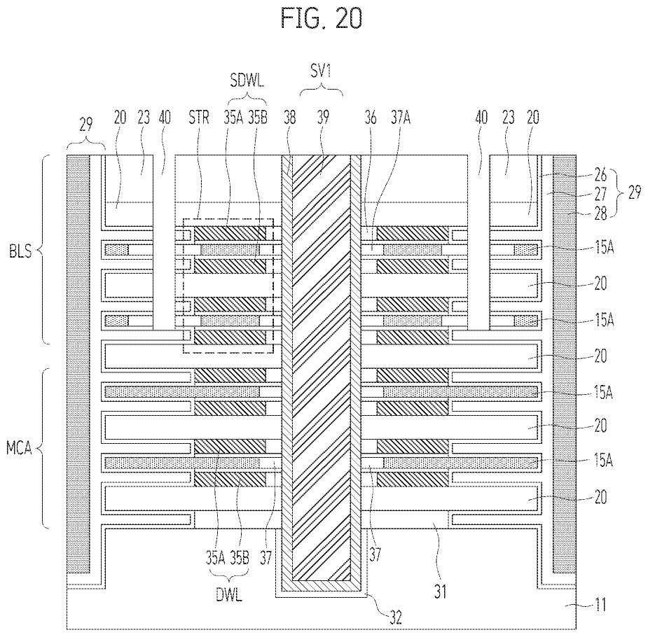

Referring to FIG. 20, a selector level contact hole 40 penetrating the preliminary horizontal layers 15A may be formed. To form the selector level contact hole 40, the top dielectric layer 23, the uppermost-level second dielectric layer 20, the vertical sacrificial structure 29, and the preliminary horizontal layers 15A disposed in the selector BLS may be etched.

The selector level contact hole 40 may be formed in the selector region BLS but may not be formed in the memory cell array MCA.

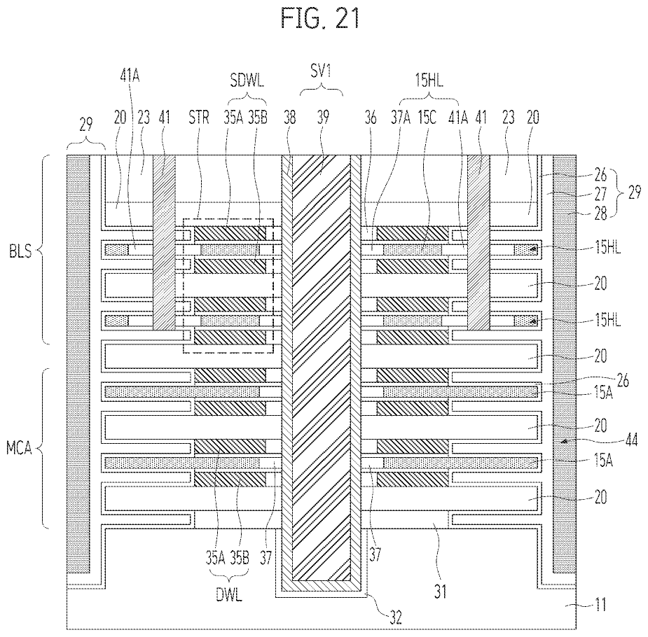

Referring to FIG. 21, a selector 41 may be formed to fill the selector level contact hole 40. The selectors 41 may have a pillar-type structure. The selectors 41 may include doped polysilicon. The selectors 41 may include a metal silicide, a metal nitride, a metal, or a combination thereof. The selectors 41 may include a stack of TiSi₂/TiN/W.

Impurities may be diffused from the selectors 41 to form a selector-level second doped region 41A. The preliminary horizontal layer 15A in which the selector-level first doped region 37A and the selector-level second doped region 41A are formed may be a selector-level horizontal layer 15HL.

As described above, a plurality of select transistors STR and the selectors 41 may be formed in the selector region BLS. The select transistors STR may include the selector-level horizontal conductive line SDWL and the selector-level horizontal layer 15HL. Each selector-level horizontal layer 15HL may include the horizontally disposed selector-level first doped region 37A and the selector-level second doped region 41A. A selector-level channel 15C may be defined between the selector-level first doped regions 37A and the selector-level second doped regions 41A. As illustrated in FIG. 2, the selector-level horizontal layers 15HL may have a cross shape, and the selector-level channels 15C may also have a cross shape.

Each selector 41 may share a plurality of select transistors STR and may be electrically connected to the vertical conductive line 39 through the select transistors STR.

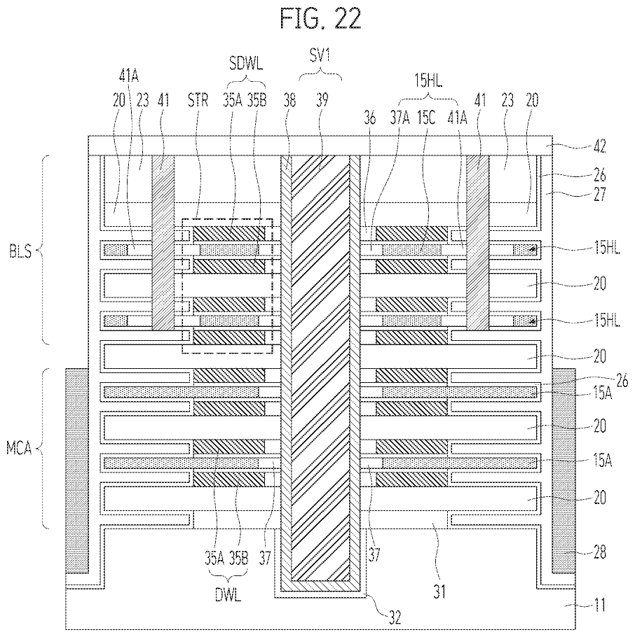

Referring to FIG. 22, after the mask layer 42 is formed, the gap-fill layer 28 of the vertical sacrificial structure 29 may be recessed from the selector region BLS. The gap-fill layer 28 may remain in the memory cell array region MCA. The top dielectric layer 23 may also be referred to as a ‘first top dielectric layer’, and the mask layer 42 may also be referred to as a ‘second top dielectric layer’.

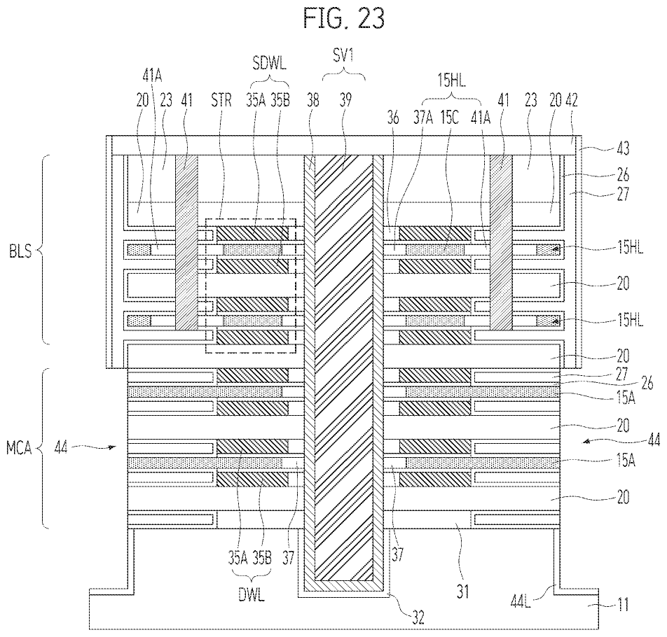

Referring to FIG. 23, a spacer 43 may be formed in the selector region BLS. The spacer 43 may be formed over the gap-fill layer 28. The spacer 43 may include a dielectric material. The spacer 43 may include silicon oxide.

The gap-fill layer 28 may be removed from the memory cell array region MCA. Subsequently, the first liner layer 26 and the second liner layer 27 may be cut. As a result, memory cell array level openings 44 may be formed. The first and second liner layers 26 and 27 that are cut may remain between the second dielectric layer 20 and the preliminary horizontal layers 15A.

Subsequently, a third passivation layer 44L may be formed on the surface of the lower structure 11. The third passivation layer 44L may include silicon oxide. The third passivation layer 44L may be formed through an oxidation process. According to another embodiment of the present invention, the third passivation layer 44L may cover the lowermost-level first liner layer 26 and the lowermost-level second liner layer 27.

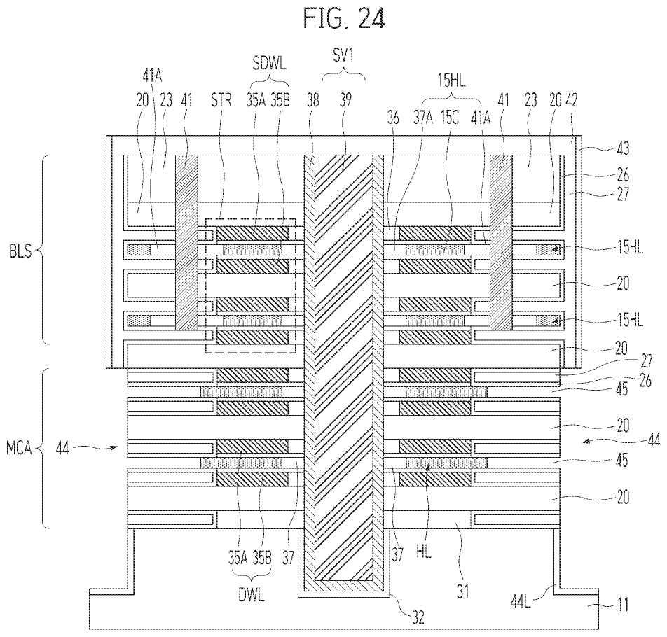

Referring to FIG. 24, the second edge portion of the preliminary horizontal layers 15A may be horizontally recessed to form recesses 45. As a result, the horizontal layers may remain as indicated by reference symbol ‘HL’.

According to the above description, a plurality of horizontal layers HL may be formed in the memory cell array region MCA. A plurality of selector-level horizontal layers 15HL may be formed in the selector region BLS. The horizontal length of the selector-level horizontal layers 15HL may be greater than the horizontal length of the horizontal layers HL. The selectors 41 may be coupled to the selector-level horizontal layers 15HL but may not be coupled to the horizontal layers HL. The bottom surfaces of the selectors 41 may be blocked by the first liner layer 26 and the second liner layer 27.

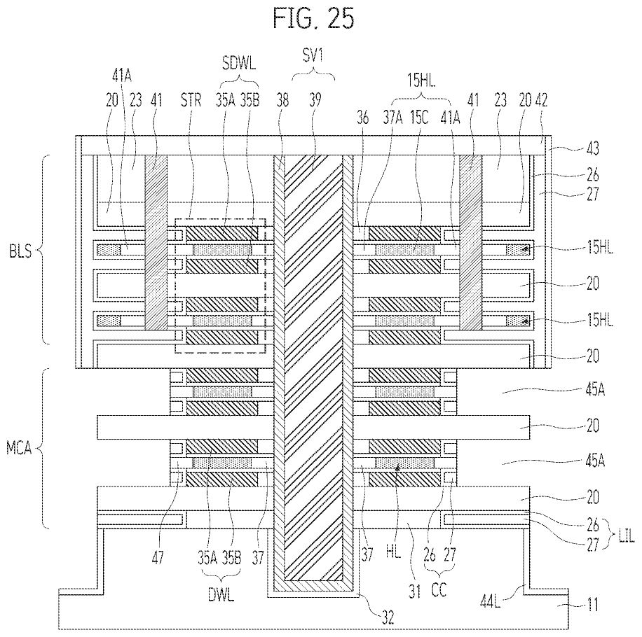

Referring to FIG. 25, the first liner layer 26 and the second liner layer 27 may be recessed from the memory cell array level openings 44. As a result, storage openings 45A may be formed in the memory cell array region MCA. An end of a second side of the horizontal layer HL may be exposed by the storage opening 45A. The storage openings 45A may also be referred to as capacitor openings.

The horizontal layers HL may include a first edge and a second edge. The first edge refers to a portion that is coupled to the first contact node 38 and the vertical conductive line 39, and the second edge refers to a portion that is exposed by the storage openings 45A.

The storage openings 45A may be disposed between the second dielectric layers 20. Second capping layers CC may be disposed in the lower and upper portions of the horizontal layers HL, respectively. The second capping layers CC may include a stack of the first liner layer 26 and the second liner layer 27.

A lowermost-level dielectric layer LIL may be formed between the lower structure 11 and the lowermost-level second dielectric layer 20. The lowermost-level dielectric layer LIL may include a stack of the first liner layer 26 and the second liner layer 27. A portion of the third passivation layer 44L may extend to cover the lowermost-level dielectric layer LIL. Accordingly, the lowermost-level dielectric layer LIL may be prevented from being lost while the storage openings 45A are formed.

The storage openings 45A may not be formed in the selector region BLS.

Subsequently, second doped regions 47 may be formed in the second edges of the horizontal layers HL, respectively. Forming the second doped regions 47 may include depositing polysilicon that is doped with an N-type impurity, performing a heat treatment, and removing the doped polysilicon. The second doped regions 47 may include impurities diffused from the doped polysilicon. According to another embodiment of the present invention, after the heat treatment, the doped polysilicon may remain.

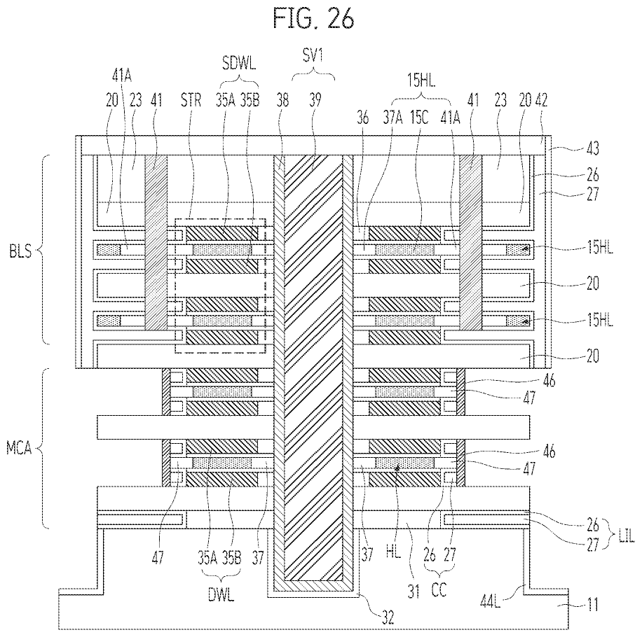

Referring to FIG. 26, second contact nodes 46 may be formed over second edges of the horizontal layers HL. The second contact nodes 46 may include doped polysilicon. The second doped regions 47 may include impurities diffused from the second contact nodes 46. According to another embodiment of the present invention, after the second contact node 46 is formed, the impurities may be diffused from the second contact node 46 to form the second doped region 47. The second contact nodes 46 may be disposed in the storage openings 45A, respectively.

The second contact nodes 46 and the storage openings 45A may be formed in the memory cell array region MCA but may not be formed in the selector region BLS.

Each horizontal layer HL may include the first doped region 37 and the second doped region 47 arranged horizontally. As illustrated in FIG. 3, a channel may be defined between the first doped regions 37 and the second doped regions 47. As illustrated in FIG. 3, the horizontal layers HL may have a cross shape, and the channels may also have a cross shape.

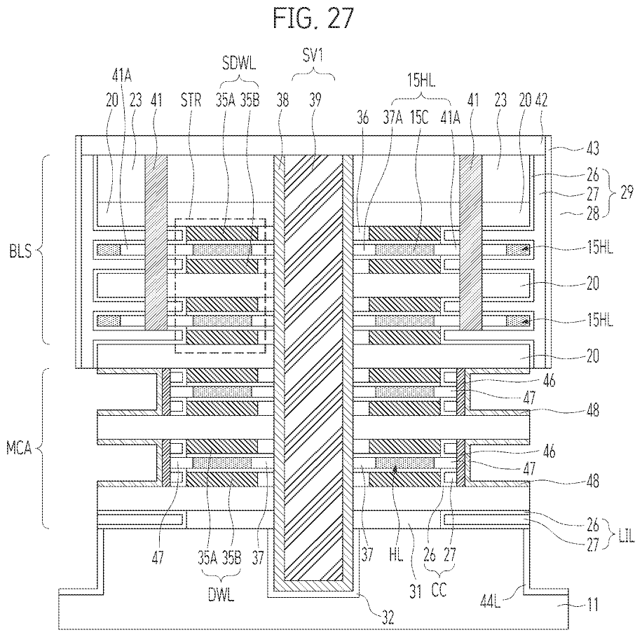

Referring to FIG. 27, first electrodes 48 of the data storage element may be formed over the second contact nodes 46. The first electrodes 48 may have a horizontally oriented cylindrical shape. The first electrodes 48 may be disposed in the storage openings 45A, respectively.

The first electrodes 48 may be formed in the memory cell array region MCA but may not be formed in the selector region BLS.

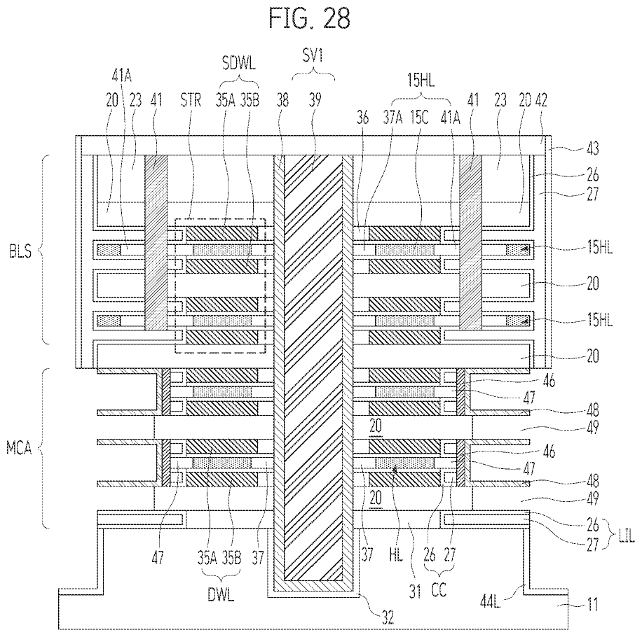

Referring to FIG. 28, the second dielectric layers 20 may be horizontally recessed (see a reference numeral 49). As a result, the outer walls of the first electrodes 48 may be exposed. The recessed second dielectric layers 20 may correspond to the inter-cell dielectric layer IL as illustrated in FIG. 1B.

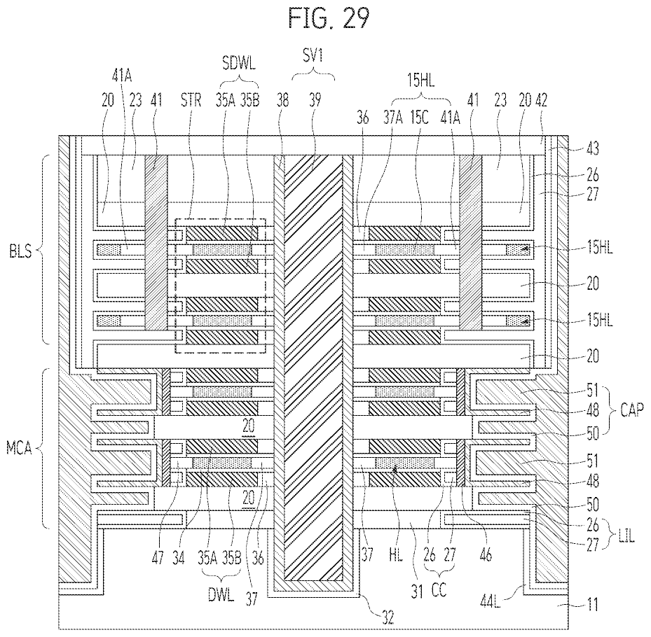

Referring to FIG. 29, a dielectric layer 50 and a second electrode 51 may be sequentially formed over the first electrodes 48. The first electrode 48, the dielectric layer 50 and the second electrode 51 may be a data storage element CAP. The dielectric layer 50 and the second electrode 51 may be formed in the memory cell array region MCA and may extend to be disposed in the selector region BLS. The dielectric layer and the second electrode extended to be disposed in the selector region BLS may correspond to the selector level dielectric layer SDE and the selector level plate SPN as illustrated in FIG. 1B.

Each first electrode 48 may include an inner space and a plurality of outer surfaces, and the inner space of the first electrode 48 may include a plurality of inner surfaces. The outer surfaces of the first electrode 48 may include a vertical outer surface and a plurality of horizontal outer surfaces. The inner space of the first electrode 48 may be a three-dimensional space. The dielectric layer 50 may conformally cover the inner and outer surfaces of the first electrode 48. The second electrode 51 may be disposed in the inner space of the first electrode 48 over the dielectric layer 50. A portion of the outer surfaces of the first electrode 48 may be electrically connected to the second doped region 47 and the second contact node 46 of the horizontal layer HL.

The first electrode 48 may have a cylindrical shape. The cylindrical shape of the first electrode 48 may include cylindrical inner surfaces and cylindrical outer surfaces. A portion of the cylindrical outer surfaces of the first electrode 48 may be electrically connected to the second doped region 47 and the second contact node 46 of the horizontal layer HL. The dielectric layer 50 and the second electrode 51 may be disposed on the cylindrical inner surfaces of the first electrode 48. The second electrode 51 may extend vertically.

The first electrode 48 and the second electrode 51 may include a metal, a noble metal, a metal nitride, a conductive metal oxide, a conductive noble metal oxide, a metal carbide, a metal silicide, or a combination thereof. For example, the first electrode 48 and the second electrode 51 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode 51 may include a combination of a metal-based material and a silicon-based material. For example, the second electrode 51 may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material that fills the inner space of the first electrode 48, and titanium nitride (TiN) may serve as the second electrode 51 of the data storage element CAP, and tungsten nitride may be a low-resistance material.

The dielectric layer 50 may also be referred to as a capacitor dielectric layer or a memory layer. The dielectric layer 50 may include silicon oxide, silicon nitride, a high-k material, a ferroelectric material, an antiferroelectric material, or a combination thereof. The dielectric layer 50 may include a high-k material, such as hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). The dielectric layer 50 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack.

According to another embodiment of the present invention, an interface control layer for improving leakage current may be further formed between the first electrode 48 and the dielectric layer 50. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 51 and the dielectric layer 59.

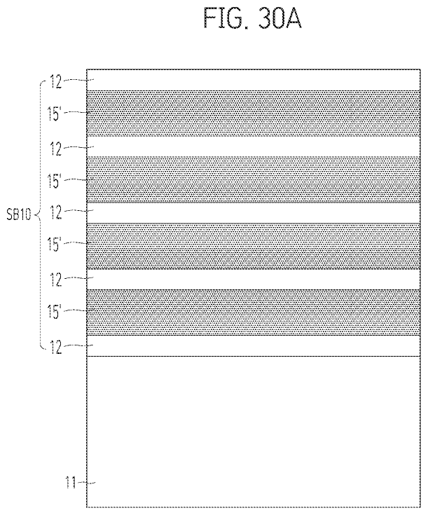

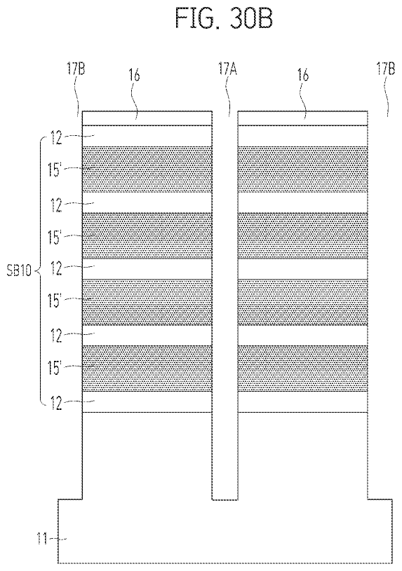

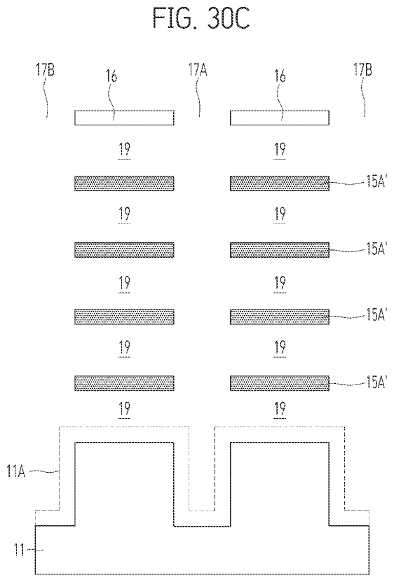

FIGS. 30A to 30C are cross-sectional view schematics illustrating a method for fabricating a semiconductor device in accordance with another embodiment of the present invention.

Referring to FIG. 30A, a stack body SB10 may be formed over the lower structure 11. The stack body SB10 may include an alternating stack of first semiconductor layers and second semiconductor layers. For example, the alternating stack may include a plurality of silicon germanium layers 12 and a plurality of monocrystalline silicon layers 15′ that are alternately stacked by epitaxial growth. The silicon germanium layers 12 may be sacrificial layers, and the monocrystalline silicon layers 15′ may be recess target layers. The silicon germanium layers 12 may correspond to the first layers 12 or the third layers 14 of FIG. 4, and the monocrystalline silicon layers 15′ may correspond to the fourth layers 15 of FIG. 4. Unlike the stack body SB of FIG. 4, the stack body SB10 is formed of an alternating stack of the silicon germanium layers 12 and the monocrystalline silicon layers 15′.

Referring to FIG. 30B, a hard mask layer pattern 16 may be formed over the stack body SB10.

Subsequently, the stack body SB10 may be etched by using the hard mask layer pattern 16 as an etch barrier. As a result, a plurality of first and second sacrificial vertical openings 17A and 17B may be formed in the stack body SB10.

Referring to FIG. 30C, preliminary horizontal layers 15A′ and horizontal recesses 19 may be formed. The preliminary horizontal layers 15A′ and the horizontal recesses 19 may be formed by a process of recessing the silicon germanium layers 12 and the monocrystalline silicon layers 15′ of FIG. 30B. After the silicon germanium layers 12 are removed, the process of recessing the monocrystalline silicon layers 15′ may be performed. The preliminary horizontal layers 15A′ may correspond to the preliminary horizontal layers 15A of FIG. 6.

To recess the silicon germanium layers 12, a wet etching process or a dry etching process may be performed. The silicon germanium layers 12 may be etched by using an etchant or an etching gas having a selectivity for the silicon geranium layers 12.

The process of recessing the monocrystalline silicon layers 15′ for forming the preliminary horizontal layers 15A′ may use, for example, HSC1 (Hot SC-1). HSC1 may include a solution of ammonium hydroxide (NH₄OH), hydrogen peroxide (H₂O₂), and water (H₂O) that are mixed at a ratio of approximately 1:4:20. The monocrystalline silicon layers 15′ may be selectively etched by using HSC1.

After the preliminary horizontal layers 15A′ are formed, the first and second sacrificial vertical openings 17A and 17B may be expanded. While the preliminary horizontal layers 15A′ are formed, the surface of the lower structure 11 may be recessed to a predetermined depth (see a reference numeral ‘11A’). As a result, the depth of the first and second sacrificial vertical openings 17A and 17B may increase.

Subsequently, a series of the processes shown in FIGS. 7 to 29 may be performed.

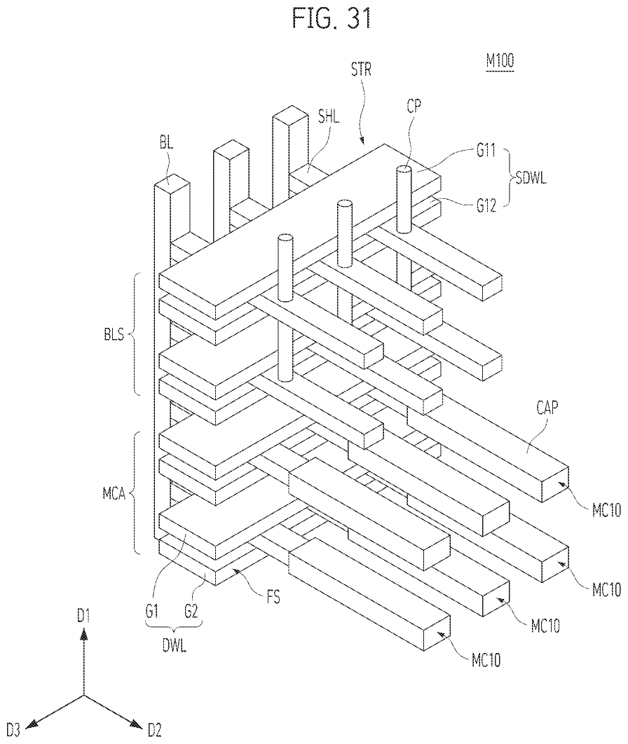

FIGS. 31 to 33 are perspective view schematics illustrating semiconductor devices in accordance with other embodiments of the present invention. The semiconductor devices M100, M200, and M300 may be similar to the semiconductor device 100 of FIGS. 1A and 1B. Hereinafter, as for the detailed descriptions on the constituent elements also appearing in FIGS. 1A and 1B, the above-described embodiments of the present invention may be referred to.

Referring to FIG. 31, the semiconductor device M100 may include a memory cell array MCA and a selector structure BLS. The selector structure BLS may be disposed over the memory cell array MCA.

The memory cell array MCA may include a three-dimensional array of memory cells MC10. The three-dimensional array of memory cells MC10 may include a column array of memory cells MC10 and a row array of memory cells MC10. The column array of memory cells MC10 may include a plurality of memory cells MC10 that are stacked in the first direction D1, and the row array of memory cells MC10 may include a plurality of memory cells MC10 that are horizontally arranged in the second direction D2 and the third direction D3.

Each memory cell MC10 may include a first conductive line BL, a switching element TR, and a data storage element CAP. As for the detailed descriptions on the first conductive line BL and the data storage element CAP, the above-described embodiments of the present invention may also be referred to.

The switching element TR may include a horizontal layer HL and a second conductive line DWL. The horizontal layer HL may extend in the second direction D2. The second conductive line DWL may extend in the third direction D3.

The second conductive line DWL may have a double structure. For example, the second conductive line DWL may include an upper horizontal line G1 and a lower horizontal line G2 that are facing each other with the horizontal layer HL interposed between them. As illustrated in FIG. 1B, an inter-level dielectric layer GD may be formed on the upper and lower surfaces of the horizontal layer HL.

Each of the upper and lower horizontal lines G1 and G2 may include a pair of flat sidewalls FS extending in the third direction D3. The flat sidewalls FS refers to vertical sidewalls. The flat sidewalls FS may have a linear shape extending in the third direction D3.

The selector structure BLS may include a plurality of select transistors STR and a selector CP. Each select transistor STR may include a selector-level horizontal layer SHL and a selector-level horizontal conductive line SDWL. The selector-level horizontal conductive line SDWL may have a double structure. For example, the selector-level horizontal conductive line SDWL may include an upper horizontal line G11 and a lower horizontal line G12 that are facing each other with the selector-level horizontal layer SHL interposed between them.

The selector CP may be a pillar-type plug that vertically passes through the selector-level horizontal layers SHL. A plurality of vertically stacked select transistors STR may share a selector CP.

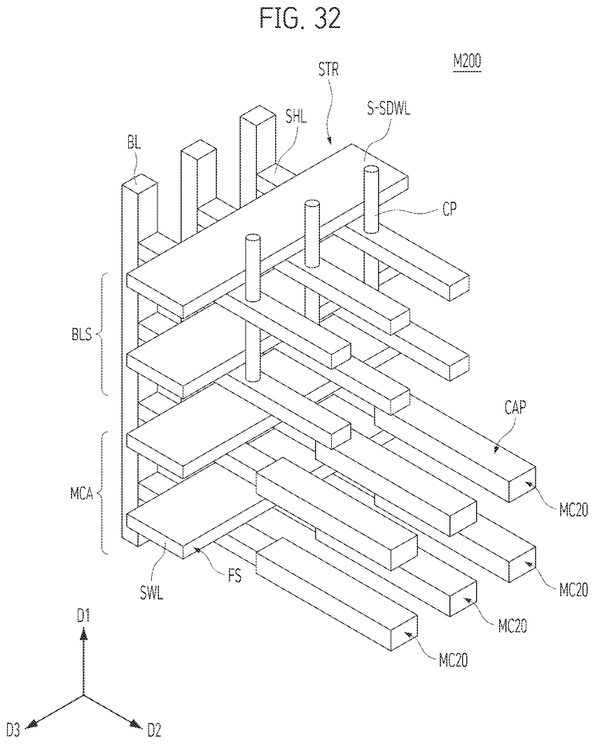

Referring to FIG. 32, the semiconductor device M200 may include a memory cell array MCA and a selector structure BLS. The selector structure BLS may be disposed over the memory cell array MCA.

The memory cell array MCA may include a three-dimensional array of memory cells MC20. The three-dimensional array of memory cells MC20 may include a column array of memory cells MC20 and a row array of memory cells MC20. The column array of memory cells MC20 may include a plurality of memory cells MC20 that are stacked in the first direction D1, and the row array of memory cells MC20 may include a plurality of memory cells MC20 that are horizontally arranged in the second direction D2 and the third direction D3.

Each memory cell MC20 may include a first conductive line BL, a switching element TR, and a data storage element CAP. As for the detailed descriptions on the first conductive line BL and the data storage element CAP, the above-described embodiments of the present invention may also be referred to.

The switching element TR may include a horizontal layer HL and a second conductive line SWL. The horizontal layer HL may extend in the second direction D2. The second conductive line SWL may extend in the third direction D3.

The second conductive line SWL may have a single structure. For example, the second conductive line SWL may be disposed over the horizontal layer HL. As illustrated in FIG. 1B, an inter-level dielectric layer GD may be formed between the upper surface of the horizontal layer HL and the second conductive line SWL. According to another embodiment of the present invention, the second conductive line SWL may be disposed below the horizontal layer HL.

The second conductive line SWL may include a pair of flat sidewalls FS extending in the third direction D3. The flat sidewalls FS refers to vertical sidewalls.

The selector structure BLS may include a plurality of select transistors STR and a selector CP. Each select transistor STR may include a selector-level horizontal layer SHL and a selector-level horizontal conductive line S-SDWL. The selector-level horizontal conductive line S-SDWL may have a single structure. For example, the selector-level horizontal conductive line S-SDWL may be disposed over the selector-level horizontal layer SHL.

The selector CP may be a pillar-type plug that vertically passes through the selector-level horizontal layers SHL. A plurality of vertically stacked select transistors STR may share a selector CP.

According to another embodiment of the present invention, the second conductive line SWL may include a channel overlapping portion WLP and a channel non-overlapping portion NOL, as illustrated to in FIG. 3.

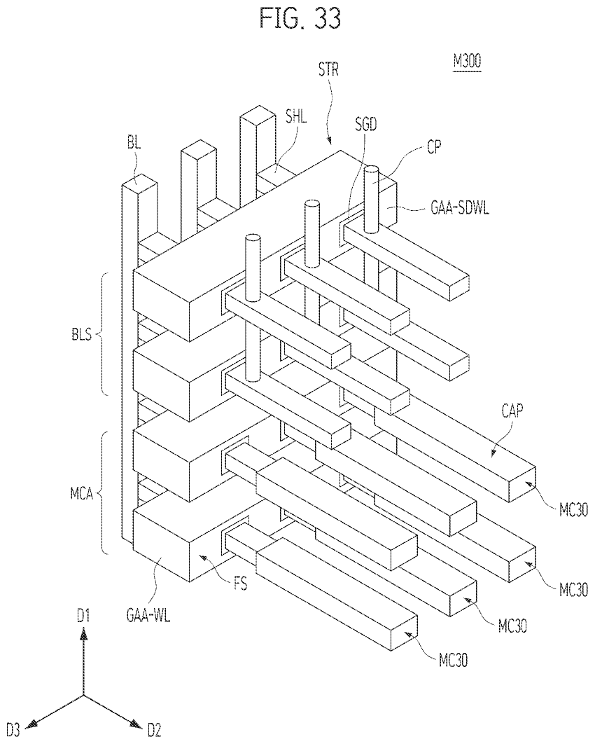

Referring to FIG. 33, the semiconductor device M300 may include a memory cell array MCA and a selector structure BLS. The selector structure BLS may be disposed over the memory cell array MCA.

The memory cell array MCA may include a three-dimensional array of memory cells MC30. The three-dimensional array of memory cells MC30 may include a column array of memory cells MC30 and a row array of memory cells MC30. The column array of memory cells MC30 may have a plurality of memory cells MC30 that are stacked in the first direction D1, and the row array of memory cells MC30 may include a plurality of memory cells MC30 that are horizontally arranged in the second direction D2 and the third direction D3.

Each memory cell MC30 may include a first conductive line BL, a switching element TR, and a data storage element CAP. As for detailed descriptions on the first conductive line BL and the data storage element CAP, the above-described embodiments of the present invention may also be referred to.

The switching element TR may include a horizontal layer HL and a second conductive line GAA-WL. The horizontal layer HL may extend in the second direction D2. The second conductive line GAA-WL may extend in the third direction D3.

The second conductive line GAA-WL may have a gate all around structure GAA. For example, the second conductive line GAA-WL may extend in the third direction D3 while surrounding the horizontal layers HL. An inter-level dielectric layer GD may be formed between the horizontal layer HL and the second conductive line GAA-WL. The inter-level dielectric layer GD may surround the individual horizontal layers HL.

The second conductive line GAA-WL may include a pair of flat sidewalls FS extending in the third direction D3. The flat sidewalls FS refers to vertical sidewalls.

The selector structure BLS may include a plurality of select transistors STR and a selector CP. Each select transistor STR may include a selector-level horizontal layer SHL and a selector-level horizontal conductive line GAA-SDWL. The selector-level horizontal conductive line GAA-SDWL may be a gate all around structure GAA. For example, the selector-level horizontal conductive line GAA-SDWL may extend in the third direction D3 while surrounding the selector-level horizontal layers SHL. A selector-level inter-level dielectric layer SGD may be formed between the selector-level horizontal layer SHL and the selector-level horizontal conductive line GAA-SDWL. The selector-level inter-level dielectric layer SGD may surround the individual selector-level horizontal layers SHL.

The selector CP may be a pillar-type plug that vertically passes through the selector-level horizontal layers SHL. A plurality of vertically stacked select transistors STR may share a selector CP.

A semiconductor device in accordance with this embodiment of the present invention may include a bit line extending vertically in the first direction; a memory cell array including a plurality of horizontal layers vertically stacked in the first direction while sharing the bit line; and a selector structure disposed at a higher level than the memory cell array and coupled to the bit line, wherein the selector structure may include a plurality of selector-level horizontal layers that is coupled to the bit line, vertically stacked in the first direction, and horizontally extending in the second direction that intersects with the first direction; selector level word lines extending in the third direction that intersects with the selector-level horizontal layers; and a pillar-type selector that vertically passes through the selector-level horizontal layers.

A semiconductor device in accordance with this embodiment of the present invention may include a bit line extending vertically in the first direction; a memory cell array including a plurality of cell transistors vertically stacked in the first direction while sharing the bit line; and a selector structure operatively coupled to the bit line, wherein the selector structure may include a plurality of select transistors that are coupled to the bit line and vertically stacked in the first direction, and a pillar-type selector commonly coupled to the select transistors.

A method for fabricating a semiconductor device in accordance with this embodiment of the present invention may include forming a stack body by stacking cell level horizontal layers and selector-level horizontal layers; forming a horizontal word line that intersects with each of the cell level horizontal layers; forming a selector level word line that intersects with each of the selector-level horizontal layers; forming a vertical bit line commonly coupled to the cell level horizontal layers and the selector-level horizontal layers; forming data storage elements coupled to the cell level horizontal layers; forming a selector level contact hole by etching the selector-level horizontal layers; and forming a pillar-type selector in the selector level contact hole.

A method for fabricating a semiconductor device in accordance with this embodiment of the present invention may include forming a bit line extending vertically over a lower structure; forming a memory cell array including a plurality of cell transistors stacked vertically while sharing the bit line; forming a bit line selector including a plurality of select transistors that are disposed at a higher level than the memory cell array; and forming a selector-level plug that is commonly coupled to the select transistors.

According to the embodiment of the present invention, the sensing margin may be increased by forming a three-dimensional memory cell array and a selector of a multi-cell structure, thereby improving the yield.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device, comprising:
a common conductive line extending in a first direction;
a memory cell array including a plurality of horizontal layers stacked in the first direction while sharing the common conductive line; and
a selector structure operatively coupled to the common conductive line,
wherein the selector structure includes,
a plurality of select transistors stacked in the first direction; and
a selector commonly coupled to the select transistors.

2. The semiconductor device of claim 1, wherein the select transistors are commonly coupled to the common conductive line and the selector.

3. The semiconductor device of claim 1, wherein the selector includes a semiconductor material, a metal, a metal silicide, a metal nitride, or a combination thereof.

4. The semiconductor device of claim 1, wherein the selector structure is disposed at a higher level than the memory cell array.

5. The semiconductor device of claim 1, wherein each of the select transistors includes:
a selector-level horizontal layer extending horizontally in a second direction that intersects with the first direction; and
a selector-level horizontal conductive line extending horizontally in a third direction that intersects with the selector-level horizontal layer.

6. The semiconductor device of claim 5, wherein the selector-level horizontal layers and the horizontal layers include the same material.

7. The semiconductor device of claim 5, wherein the selector-level horizontal layers and the horizontal layers include a monocrystalline silicon, polysilicon, or an oxide semiconductor material.

8. The semiconductor device of claim 5, wherein the selector includes
a pillar-shaped structure penetrating the selector-level horizontal layers.

9. The semiconductor device of claim 5, wherein the memory cell array further includes
a plurality of horizontal conductive lines extending in the third direction that intersects with each of the horizontal layers.

10. The semiconductor device of claim 9, wherein each of the horizontal conductive lines and the selector-level horizontal conductive lines includes
a single structure, a double structure, or a gate all around structure.

11. The semiconductor device of claim 1, wherein the memory cell array further includes
a plurality of data storage elements that are coupled to second sides of the horizontal layers, respectively.

12. The semiconductor device of claim 11, wherein each of the data storage elements includes:
a first electrode having a cylindrical shape;
a dielectric layer over the first electrode; and
a second electrode over the dielectric layer,
wherein the dielectric layer and the second electrode extend to be horizontally spaced apart from the selector.

13. The semiconductor device of claim 1, wherein the common conductive line is a bit line, and
the selector is a bit line selector.
